(19) United States
(12) Patent Application Publication
(10) Pub. No.: US 2024/0172494 A1
(43) Pub. Date: May 23, 2024

(54) DISPLAY APPARATUS AND METHOD OF MANUFACTURING THE SAME

(71) Applicant: Samsung Display Co., Ltd., Yongin-si (KR)

(72) Inventors: Jewon Yoo, Yongin-si (KR); Dongjo Kim, Yongin-si (KR); Youngji Kim, Yongin-si (KR); Hyun Kim, Yongin-si (KR); Seonggeun Won, Yongin-si (KR); Seungmin Lee, Yongin-si (KR); Soukjune Hwang, Yongin-si (KR)

(73) Assignee: Samsung Display Co., Ltd., Yongin-si (KR)

(21) Appl. No.: 18/513,749

(22) Filed: Nov. 20, 2023

(30) Foreign Application Priority Data
Nov. 22, 2022 (KR) 10-2022-0157505
May 12, 2023 (KR) 10-2023-0061733

(51) Int. Cl. H10K 59/127; H10K 59/12; H10K 77/10

(52) U.S. Cl. CPC H10K 59/127; H10K 59/1201; H10K 77/111; H10K 2102/311

(57) ABSTRACT

Provided are a display apparatus and a method of manufacturing the display apparatus. The display apparatus includes a support substrate including a first support substrate and a second support substrate spaced apart from each other, a substrate disposed on the support substrate, a display layer disposed on a portion of the substrate disposed on the first support substrate, and a thin-film encapsulation layer disposed to cover the display layer, wherein a surface of the first support substrate and a surface of the second support substrate facing each other include a slope surface.

### CROSS-REFERENCE TO RELATED APPLICATION(S)

This application claims priority under 35 U.S.C. § 119 to and benefits of Korean Patent Application No. 10-2022-0157505, filed on Nov. 22, 2022, and 10-2023-0061733, filed on May 12, 2023, in the Korean Intellectual Property Office, the entire contents of which are incorporated herein by reference.

### BACKGROUND

### 1. Technical Field

One or more embodiments relate to a display apparatus and a method of manufacturing the display apparatus.

### 2. Description of the Related Art

Mobile electronic apparatuses are widely used. Recently, mobile electronic apparatuses, e.g., tablet personal computers (PCs), and miniaturized electronic apparatuses, e.g., mobile phones, are widely used.

To support various functions, for example, to provide a user with visual information, such as images, the mobile electronic apparatuses include a display apparatus. In a display apparatus, a display circuit board may be disposed on the rear surface of a display panel in order to increase a display area and miniaturize the mobile electronic apparatuses.

### SUMMARY

In a display apparatus, a substrate is bent to attach a display circuit board to the rear surface of a display panel, and a separate support substrate is used to support the substrate. For example, an opening area is formed in the support substrate, but a cross-section of the support substrate has a vertical shape in the opening area. Accordingly, in case that the substrate is bent, the substrate may be damaged or excessively supported, and thus, a curvature radius may increase. For example, as a protective film is used to form the opening area, excessive foreign materials may remain on the display panel after the display panel is manufactured. Accordingly, the deterioration in the performance or defects of the display apparatus may be caused.

Embodiments provide a display apparatus capable of supporting a substrate after the substrate is bent, supporting force applied to the substrate, and improving quality by preventing or minimizing foreign materials while the display apparatus is manufactured, and a method of manufacturing the display apparatus.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a display apparatus may include a support substrate including a first support substrate and a second support substrate spaced apart from each other, a substrate disposed on the support substrate, a display layer disposed on a portion of the substrate disposed on the first support substrate, and a thin-film encapsulation layer disposed to cover the display layer, wherein a surface of the first support substrate and a surface of the second support substrate facing each other may include a slope surface.

One of the surface of the first support substrate and the surface of the second support substrate facing each other may include a groove extending in a direction away from another one of the surface of the first support substrate and the surface of the second support substrate facing each other.

A maximum width of the groove may be greater than 0 μm and may be equal to or less than 50 μm.

Each of the first support substrate and the second support substrate may include a plurality of sides, and at least one of the plurality of sides of the first support substrate or at least one of the plurality of sides of the second support substrate may include the slope surface.

The display apparatus may further include a protective layer disposed on the support substrate and the substrate.

The protective layer may overlap a region in which the first support substrate is spaced apart from the second support substrate in a plan view.

The protective layer may include amorphous silicon.

The substrate may be bent to form a bent portion.

The display apparatus may further include a bending protective layer disposed on the bent portion of the substrate.

According to one or more embodiments, a method of manufacturing a display apparatus may include disposing a second base substrate on a first base substrate, forming a display layer and a thin-film encapsulation layer on the second base substrate, forming a reference groove in the first base substrate, disposing an etching protective layer on the thin-film encapsulation layer, and forming an opening area by spraying an etching solution to the first base substrate and by expanding the reference groove.

The method may further include forming the reference groove by removing a portion of the first base substrate by a cutter or a laser beam.

The method may further include forming a protective layer on the first base substrate.

The protective layer may overlap the reference groove in a plan view.

The protective layer may include amorphous silicon.

A depth of the reference groove may have a linear relationship with a taper angle of a surface of the first base substrate disposed around the opening area.

The method may further include forming a groove in a boundary area of a surface of the first base substrate defining the opening area.

A maximum width of the groove may be greater than 0 μm and may be equal to or less than 50 μm.

The method may further include separating the first base substrate and the second base substrate along an edge portion of the display layer.

The method may further include disposing a bending protective layer on the second base substrate to overlap the opening area in a plan view.

The method may further include bending the second base substrate around an arbitrary bending axis overlapping the bending protective layer.

The method may further include cutting the first base substrate and the second base substrate along a cutting line spaced apart from an edge portion of the display layer and the thin-film encapsulation layer.

According to one or more embodiments, a method of manufacturing a display apparatus may include disposing a second base substrate on a first base substrate, forming a display layer and a thin-film encapsulation layer on the second base substrate, forming a cutting groove in the second base substrate, disposing an etching protective layer on the thin-film encapsulation layer, and separating a portion of the first base substrate from another portion of the first base substrate along the cutting groove by spraying an etching solution to a surface of the first base substrate different from a surface of the first base substrate on which the display layer is disposed.

These and/or other aspects will become apparent and more readily appreciated from the following detailed description of the embodiments, the accompanying drawings, and claims.

These general and specific aspects may be implemented by using a system, a method, a computer program, or a combination of a certain system, method, and computer program.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display panel according to an embodiment;

FIG. 2 is a schematic cross-sectional view of the display panel, taken along line II-II′ of FIG. 1;

FIGS. 3 and 4 are schematic diagrams of circuit diagrams of the display panel of FIG. 1;

FIG. 5A is a schematic cross-sectional view of a display apparatus according to an embodiment;

FIG. 5B is a schematic perspective view of a support substrate and a substrate of FIG. 5A;

FIG. 5C is an enlarged schematic backside view of a region A of FIG. 5B;

FIG. 6A is a schematic plan view showing manufacturing of a display apparatus according to an embodiment;

FIGS. 6B and 6C are schematic cross-sectional views showing manufacturing of a display apparatus taken along line B-B′ of FIG. 6A according to an embodiment;

FIG. 6D is a schematic plan view showing manufacturing of a display apparatus according to an embodiment;

FIG. 6E is a schematic cross-sectional view showing manufacturing of a display apparatus taken along line C-C′ of FIG. 6D according to an embodiment;

FIG. 7 is a schematic cross-sectional view of a display apparatus according to an embodiment;

FIG. 8A is a schematic plan view showing manufacturing of a display apparatus according to an embodiment;

FIGS. 8B and 8C are schematic cross-sectional views showing manufacturing of a display apparatus taken along line D-D′ of FIG. 8A according to an embodiment;

FIG. 8D is a schematic plan view showing manufacturing of a display apparatus according to an embodiment;

FIGS. 8E, 8F, and 8G are schematic cross-sectional views showing manufacturing of a display apparatus according to an embodiment;

FIG. 9 is a schematic cross-sectional view of a display apparatus according to an embodiment;

FIG. 10A is a schematic plan view showing manufacturing of a display apparatus according to an embodiment;

FIGS. 10B, 10C, and 10D are schematic cross-sectional views showing manufacturing of a display apparatus taken along line E-E′ of FIG. 10A according to an embodiment;

FIG. 11 is a schematic cross-sectional view of a display apparatus according to an embodiment;

FIG. 12A is a schematic perspective view of a portion of a display apparatus according to an embodiment;

FIG. 12B is an enlarged schematic backside view of a region D of FIG. 12A;

FIG. 12C is a schematic perspective view of a portion of FIG. 12A;

FIG. 12D is a schematic cross-sectional view of an opening area of FIG. 12A;

FIGS. 13A, 13B, and 13C are schematic backside views of an opening area of FIG. 12A;

FIGS. 14A, 14B, 14C, and 14D are schematic views showing embodiments of a cutting unit used in a method of manufacturing a display apparatus according to an embodiment; and

FIGS. 15A and 15B are schematic cross-sectional views of some of the manufacturing of a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein are interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

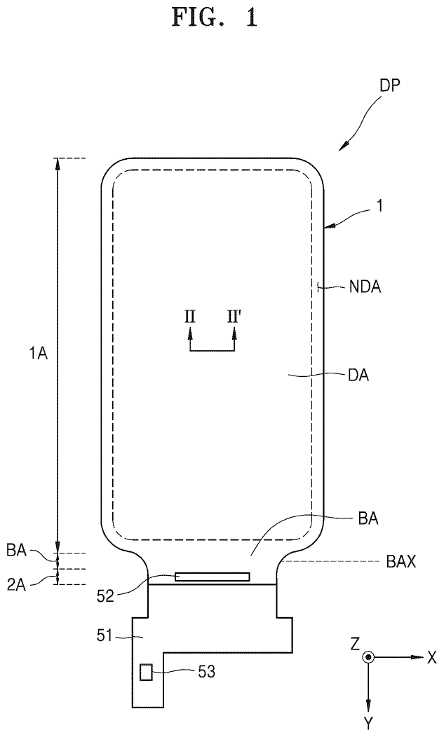

FIG. 1 is a schematic plan view of a display apparatus DP according to an embodiment.

Referring to FIG. 1, the display apparatus DP may include a display panel 1, a display circuit board 51, a display driver 52, and a touch sensor driver 53. The display panel 1 may be a light-emitting display panel including a light-emitting element. As an example, the display panel 1 may be an organic light-emitting display panel with an organic light-emitting diode that includes an organic emission layer, an ultra-miniature light-emitting diode display panel that uses a micro light-emitting diode, a quantum-dot light-emitting display panel that uses a quantum-dot light-emitting diode including a quantum-dot emission layer, or an inorganic light-emitting display panel that uses an inorganic light-emitting element including an inorganic semiconductor.

The display panel 1 may be a flexible display panel which has flexibility and thus is readily bendable, foldable, or rollable. As an example, the display panel 1 may include a foldable display panel that is foldable and unfoldable, a curved display panel that has a curved display surface, a bended display panel in which a region except a display surface is bent, a rollable display panel that is rollable and unrollable, and a stretchable display panel that is stretchable.

The display panel 1 may be a transparent display panel that is implemented to be transparent such that an object or background disposed below the display panel 1 may be viewable from the upper surface of the display panel 1. In another example, the display panel 1 may be a reflective display panel that reflects an object or background over the upper surface of the display panel 1.

The display panel 1 may include a display area DA and a peripheral area NDA arranged to surround the display area DA. The display area DA may display images. Separate driving circuit and pad, and the like may be arranged in the peripheral area NDA.

For example, the display panel 1 may include a first area 1A, a bent area BA, and a second area 2A. The first area 1A may be arranged in the display area DA, the bent area BA may be bent around a bending axis BAX, and the second area 2A may be connected to the bent area BA and the display circuit board 51. For example, the second area 2A and the bent area BA may be included in the peripheral area NDA. Images may not be displayed in the second area 2A and the bent area BA. The bent area BA connected to the first area 1A may have a length smaller than a length of a side of the first area 1A. The width of the bent area BA measured in an X axis direction of FIG. 1 may be reduced as being closer to the second area 2A from the first area 1A, and may be constant in a certain region.

The display circuit board 51 may be attached to the edge portion on the side of the display panel 1. For example, a separate pad portion may be disposed on the side of the display panel 1, and the pad portion may be connected to the display circuit board 51. For example, a side of the display circuit board 51 may be attached to the edge portion of the side of the display panel 1 by using an anisotropic conductive film. In another example, the display circuit board 51 may be connected to the display panel 1 through a flexible film. For example, one of the end portions of the flexible film may be connected to the display panel 1, and another one of the end portions of the flexible film may be connected to the display circuit board 51. The flexible film may be a flexible film that is bendable. Hereinafter, for convenience of description, the case where the display circuit board 51 is directly connected to the display panel 1 is described in detail.

The display circuit board 51 may be a flexible printed circuit board (FPCB) that is bendable, or a composite printed circuit board including both a rigid printed circuit board that is strong and not readily bent and a flexible printed circuit board.

In an embodiment, the display driver 52 may be disposed on the display panel 1. For example, the display driver 52 may be disposed on a substrate or a support substrate of the display panel 1. The display driver 52 may receive control signals and power voltages, generate and output signals and voltages for driving the display panel 1. The display driver 52 may include an integrated circuit (IC). In another example, the display driver 52 may be disposed on the flexible film. Hereinafter, for convenience of description, the case where the display driver 52 is disposed on the display panel 1 is described in detail.

The touch sensor driver 53 may be disposed on the display circuit board 51. The touch sensor driver 53 may include an integrated circuit. The touch sensor driver 53 may be attached to the display circuit board 51. The touch sensor driver 53 may be electrically connected to touch electrodes of a touch electrode layer of the display panel 1 through the display circuit board 51.

The touch electrode layer of the display panel 1 may sense a user's touch input by using at least one of various touch methods such as a resistance layer method, a capacitive method and the like. As an example, in the case where the touch electrode layer of the display panel 1 senses a user's touch input by using a capacitive method, the touch sensor driver 53 may determine whether a user touches the touchscreen layer by applying driving signals to driving electrodes among touch electrodes, and sensing voltages charged in a mutual capacitance between the driving electrodes and the sensing electrodes through the sensing electrodes among the touch electrodes. A user's touch may include a contact touch and a proximity touch. A contact touch denotes that an object such as a user's finger or a pen directly contacts a cover member disposed on the touch electrode layer. A proximity touch, like hovering, denotes that an object such as a user's finger or a pen is located near over the cover member or away from the cover member. The touch sensor driver 53 may transfer sensor data to a main processor according to sensed voltages, and the main processor may calculate touch coordinates at which a touch input occurs by analyzing the sensor data.

A power supply unit may be additionally disposed on the display circuit board 51. The power supply unit may supply driving voltages for driving the pixels of the display panel 1. the scan driver, and the display driver 52. In another example, the power supply unit may be integral with the display driver 52. For example, the display driver 52 and the power supply unit may be implemented in one integrated circuit.

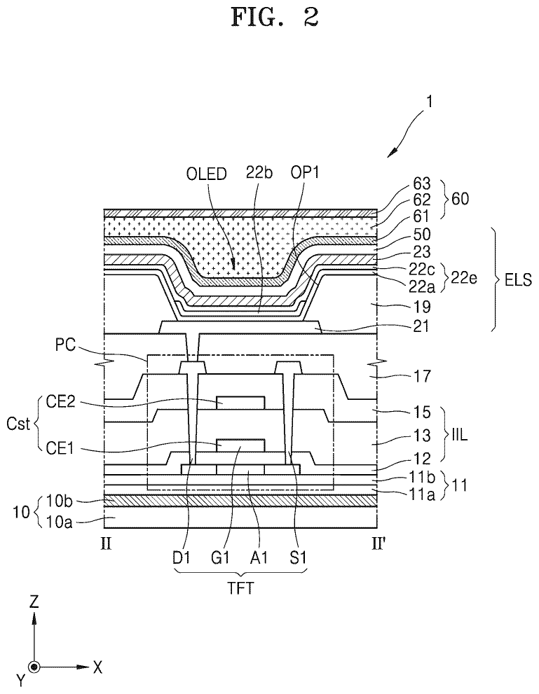

FIG. 2 is a schematic cross-sectional view of the display panel, taken along line II-II′ of FIG. 1. FIG. 2 is a schematic cross-sectional view of a portion of the display area DA of the display apparatus DP shown in FIG. 1.

Referring to FIG. 2, the display panel 1 may include a base substrate 10, a buffer layer 11, a circuit layer, and a display layer or display portion ELS including a display element layer. For example, the display panel 1 may include an encapsulation member shielding the display element layer.

The base substrate 10 may include an insulating material such as glass, quartz, and/or polymer resin and the like. The base substrate 10 may include a substrate 10b and a support substrate 10a. For example, the support substrate 10a may include an insulating material such as glass and/or quartz and the like. The support substrate 10a may include portions separated from each other. As an example, the support substrate 10a may be separated into two or three portions.

The substrate 10b may include an insulating material such as polymer resin and the like. For example, the substrate 10b may be a flexible substrate that is bendable, foldable, and rollable. In the case where the substrate 10b includes an insulating material such as polymer resin and the like, the substrate 10b may have a structure in which a layer including an organic material and a layer including an inorganic material are alternately stacked. As an example, the substrate 10b may include an organic layer and an inorganic layer. The organic layer may include one of polyimide, polyethylene naphthalate, polyethylene terephthalate, polyarylate, polycarbonate, polyetherimide, and/or polyethersulfone. The inorganic layer may include at least one of silicon oxide, silicon oxynitride, silicon nitride, and/or amorphous silicon.

The buffer layer 11 may be disposed on a substrate 10b, may reduce or block penetration of foreign materials, moisture, and/or external air from below the substrate 10b, and provide a flat surface on the substrate 10b. The buffer layer 11 may include an inorganic material, an organic material, and/or an organic/inorganic composite material, and include a single layer and/or a multi-layer including an inorganic material and an organic material, the inorganic material including oxide or nitride. A barrier layer may be further disposed between the substrate 10b and the buffer layer 11, and may block or prevent penetration of external air. In an embodiment, the buffer layer 11 may include silicon oxide (SiO₂) and/or silicon nitride (SiNₓ). The buffer layer 11 may include a first buffer layer 11a and a second buffer layer 11b that are stacked.

The circuit layer may be disposed on the buffer layer 11 and may include a pixel circuit PC, an insulating layer IIL, and a planarization layer 17. The insulating layer IIL may include a first gate insulating layer 12, a second gate insulating layer 13, and an interlayer insulating layer 15. The pixel circuit PC may include a thin-film transistor TFT and a storage capacitor Cst.

The thin-film transistor TFT may be disposed on the buffer layer 11. The thin-film transistor TFT may be connected to an organic light-emitting element OLED to drive the organic light-emitting element OLED. The thin-film transistor TFT may include a first semiconductor layer A1, a first gate electrode G1, a first source electrode S1, and a first drain electrode D1.

The first semiconductor layer A1 may be disposed on the buffer layer 11 and may include polycrystalline silicon. In another example, the first semiconductor layer A1 may include amorphous silicon. In another example, the first semiconductor layer A1 may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The first semiconductor layer A1 may include a channel region, a source region, and a drain region. The source region and the drain region may be doped with impurities.

The first gate insulating layer 12 may be provided to cover the first semiconductor layer A1. The first gate insulating layer 12 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnOₓ). For example, zinc oxide (ZnOₓ) may be zinc oxide (ZnO) and/or zinc peroxide (ZnO₂). The first gate insulating layer 12 may include a single layer or a multi-layer including the inorganic insulating material.

The first gate electrode G1 may be disposed on the first gate insulating layer 12 and may overlap the first semiconductor layer A1. The first gate electrode G1 may include at least one of molybdenum (Mo), aluminum (Al), copper (Cu), titanium (Ti) and the like and may include a single layer or a multi-layer. As an example, the first gate electrode G1 may include a single Mo layer.

The second gate insulating layer 13 may be provided to cover the first gate electrode G1. The second gate insulating layer 13 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ). For example, zinc oxide (ZnOₓ) may be zinc oxide (ZnO) and/or zinc peroxide (ZnO₂). The second gate insulating layer 13 may include a single layer or a multi-layer including the inorganic insulating material.

A first upper electrode CE2 of the storage capacitor Cst may be disposed on the second gate insulating layer 13.

The first upper electrode CE2 may overlap the first gate electrode G1 therebelow in the display area DA. The first gate electrode G1 and the first upper electrode CE2 may overlap each other, and may form the storage capacitor Cst with the second gate insulating layer 13 between the first gate electrode G1 and the first upper electrode CE2. The first gate electrode G1 may function as a first lower electrode CE1 of the storage capacitor Cst.

The first upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and may include a single layer or a multi-layer including the above materials.

The interlayer insulating layer 15 may be formed to cover the first upper electrode CE2. The interlayer insulating layer 15 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ). The interlayer insulating layer 15 may include a single layer or a multi-layer including the inorganic insulating material. For example, zinc oxide (ZnOₓ) may be zinc oxide (ZnO) and/or zinc peroxide (ZnO₂).

The first source electrode S1 and the first drain electrode D1 may be disposed on the interlayer insulating layer 15. The first source electrode S1 and the first drain electrode D1 may each include a conductive material including molybdenum (Mo), aluminum (Al), copper (Cu), and titanium (Ti) and include a single layer or a multi-layer including the above materials. As an example, the first source electrode S1 and the first drain electrode D1 may each have a multi-layered structure of Ti/Al/Ti.

The planarization layer 17 may be disposed to cover the first source electrode S1 and the first drain electrode D1. The planarization layer 17 may have a flat top surface such that a pixel electrode 21 disposed thereon may be formed to be flat.

The planarization layer 17 may include an organic material or an inorganic material and have a single-layered structure or a multi-layered structure. The planarization layer 17 may include a general-purpose polymer such as benzocyclobutene (BCB), polyimide, hexamethyldisiloxane (HMDSO), polymethylmethacrylate (PMMA) or polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. The planarization layer 17 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ). For example, zinc oxide (ZnOₓ) may be zinc oxide (ZnO) and/or zinc peroxide (ZnO₂). In case of forming the planarization layer 17, after a layer is formed, chemical mechanical polishing may be performed on an upper surface of the layer to provide a flat top surface.

The planarization layer 17 may include a via hole exposing one of the first source electrode S1 and the first drain electrode D1, and the pixel electrode 21 may be electrically connected to the thin-film transistor TFT by contacting the first source electrode S1 or the first drain electrode D1 through the via hole.

The pixel electrode 21 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). The pixel electrode 21 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. As an example, the pixel electrode 21 may have a structure including layers on/under the reflective layer, the layers including ITO, IZO, ZnO, or In₂O₃. For example, the pixel electrode 21 may have a stack structure of ITO/Ag/ITO.

A pixel-defining layer 19 may cover the edge portions of the pixel electrode 21 on the planarization layer 17 and may include a first opening OP1 exposing the central portion of the pixel electrode 21. An emission area of the organic light-emitting element OLED, e.g., the size and shape of a sub-pixel, may be defined by the first opening OP1.

The pixel-defining layer 19 may prevent arcs and the like from occurring at the edge portions of each pixel electrode 21 by increasing a distance between the edge portions of each pixel electrode 21 and an opposite electrode 23 over the pixel electrode 21. The pixel-defining layer 19 may include an organic insulating material, such as polyamide, an acryl resin, benzocyclobutene, and hexamethyldisiloxane (HMDSO), and may be formed by a spin coating process and the like.

An emission layer 22b may be disposed inside of the first opening OP1 of the pixel-defining layer 19. The emission layer 22b may correspond to each pixel electrode 21. The emission layer 22b may include a low-molecular weight material or a polymer material, and emit red light, green light, blue light, or white light.

An organic functional layer 22e may be disposed on and/or under the emission layer 22b. The organic functional layer 22e may include a first functional layer 22a and/or a second functional layer 22c. In another example, the first functional layer 22a or the second functional layer 22c may be omitted.

The first functional layer 22a may be disposed under the emission layer 22b. The first functional layer 22a may include a single layer or a multi-layer including an organic material. The first functional layer 22a may be a hole transport layer (HTL) having a single-layered structure. In another example, the first functional layer 22a may include a hole injection layer (HIL) and a hole transport layer (HTL). The first functional layer 22a may be integrally formed to correspond to organic light-emitting elements OLED included in the display area DA.

The second functional layer 22c may be disposed on the emission layer 22b. The second functional layer 22c may include a single layer or a multi-layer including an organic material. The second functional layer 22c may include an electron transport layer (ETL) and/or an electron injection layer (EIL). The second functional layer 22c may be integrally formed to correspond to the organic light-emitting elements OLED included in the display area DA.

The opposite electrode 23 may be disposed on the second functional layer 22c. The opposite electrode 23 may include a conductive material having a low work function. As an example, the opposite electrode 23 may include a semi-transparent layer (or a transparent layer) including silver (Ag), magnesium (Mg), aluminum (Al), platinum (Pt), palladium (Pd), gold (Au), nickel (Ni), neodymium (Nd), iridium (Ir), chrome (Cr), or an alloy thereof. In another example, the opposite electrode 23 may further include a layer that is disposed on the semi-transparent layer (or the transparent layer) and includes ITO, IZO, ZnO, or In₂O₃. The opposite electrode 23 may be integrally formed to correspond to the organic light-emitting elements OLED included in the display area DA.

Layers from the pixel electrode 21 to the opposite electrode 23 formed in the display area DA may form the organic light-emitting element OLED.

An upper layer 50 including an organic material may be formed on the opposite electrode 23. The upper layer 50 may be a layer for protecting the opposite electrode 23 and simultaneously increasing a light-extracting efficiency. The upper layer 50 may include an organic material having a higher refractive index than that of the opposite electrode 23. In another example, the upper layer 50 may include layers of different refractive indexes that are stacked. As an example, the upper layer 50 may include a high refractive index layer/a low refractive index layer/a high refractive index layer that are stacked. For example, the refractive index of the high refractive index layer may be about 1.7 or more, and the refractive index of the low refractive index layer may be about 1.3 or less.

The upper layer 50 may additionally include lithium fluoride (LiF). In another example, the upper layer 50 may additionally include an inorganic insulating material such as silicon oxide (SiO₂) and silicon nitride (SiNₓ). In another example, the upper layer 50 may be omitted. However, for convenience of description, the case where the upper layer 50 is disposed on the opposite electrode 23 is described in detail.

For example, the display apparatus DP may include the encapsulation member for shielding the upper layer 50. For example, the encapsulation member may include a thin-film encapsulation layer 60 for shielding the upper layer 50.

The thin-film encapsulation layer 60 may be disposed on the upper layer 50 to contact (e.g., directly contact) the upper layer 50. For example, the thin-film encapsulation layer 60 may prevent penetration of external moisture and oxygen by covering a portion of the display area DA and the peripheral area NDA. The thin-film encapsulation layer 60 may include at least one inorganic encapsulation layer and at least one organic encapsulation layer. Hereinafter, for convenience of description, the case where the thin-film encapsulation layer 60 includes a first inorganic encapsulation layer 61, an organic encapsulation layer 62, and a second inorganic encapsulation layer 63 that are sequentially stacked on the upper layer 50 is described in detail.

For example, the first inorganic encapsulation layer 61 may cover the upper layer 50 and may include silicon oxide, silicon nitride, and/or silicon oxynitride. As the first inorganic encapsulation layer 61 is formed along a structure thereunder, the upper surface of the first inorganic encapsulation layer 61 may not be flat. The organic encapsulation layer 62 may cover the first inorganic encapsulation layer 61 and, unlike the first inorganic encapsulation layer 61, the upper surface of the organic encapsulation layer 62 may be substantially flat. For example, the upper surface of a portion of the organic encapsulation layer 62 that corresponds to the display area DA may be substantially flat. The organic encapsulation layer 62 may include at least one material among polyethylene terephthalate, polyethylene naphthalate, polycarbonate, polyimide, polyethylene sulfonate, polyoxymethylene, polyarylate, and hexamethyldisiloxane. The second inorganic encapsulation layer 63 may cover the organic encapsulation layer 62 and may include silicon oxide, silicon nitride, and/or silicon oxynitride.

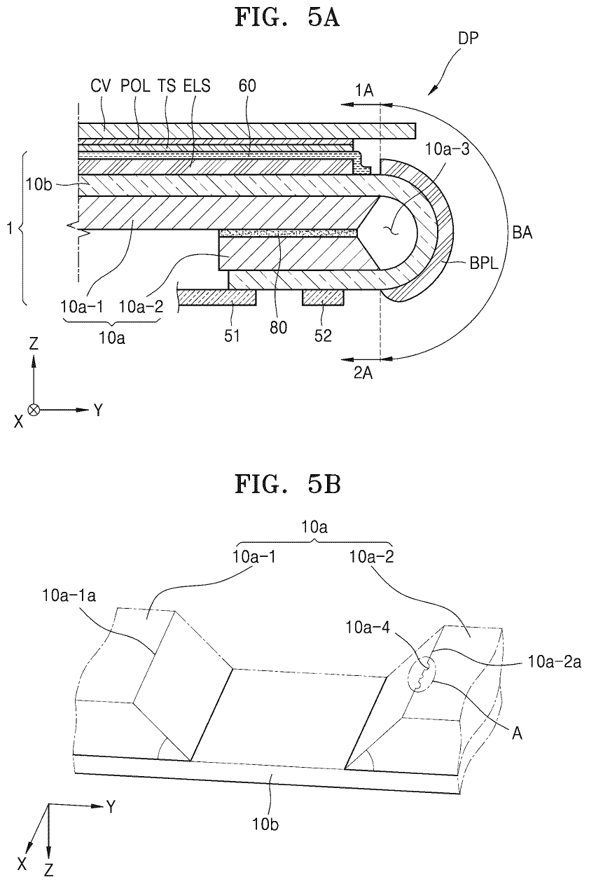

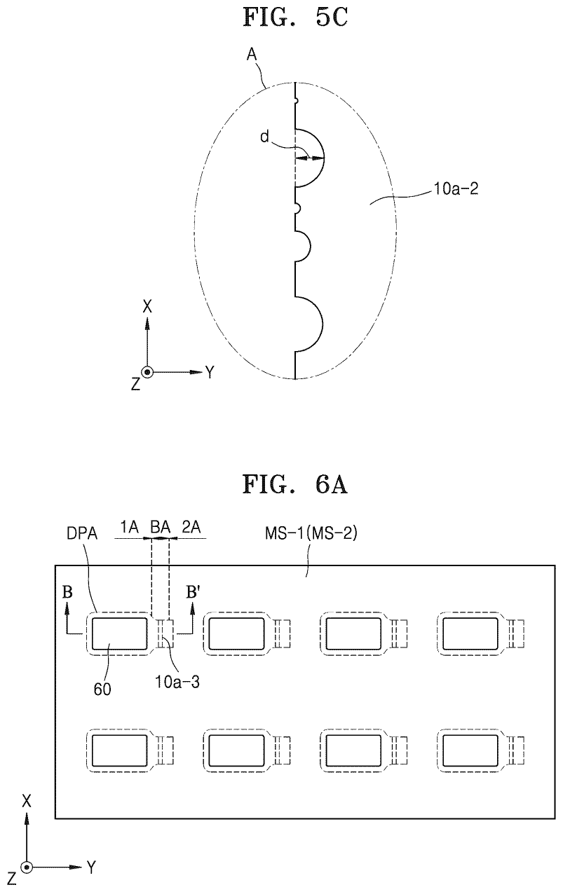

A touch electrode layer (e.g., TS in FIG. 5A) may be disposed on the thin-film encapsulation layer 60.

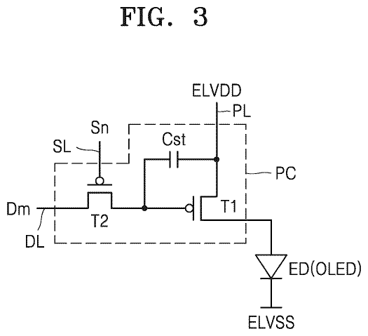

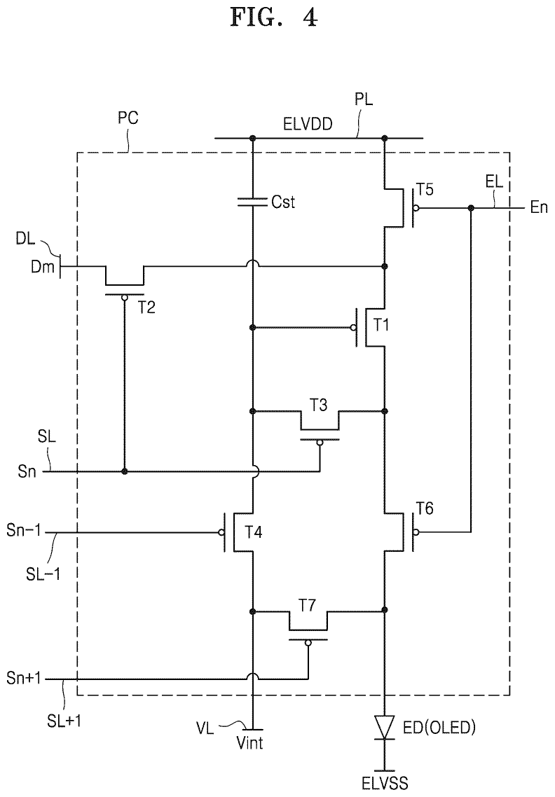

FIGS. 3 and 4 are circuit diagrams of the display panel shown in FIG. 1.

Referring to FIGS. 3 and 4, the pixel circuit PC may be connected to a light-emitting element ED to implement light emission of sub-pixels. For example, the light-emitting element ED may include the organic light-emitting element OLED shown in FIG. 2. The pixel circuit PC may include a driving thin-film transistor T1, a switching thin-film transistor T2, and a storage capacitor Cst. The switching thin-film transistor T2 may be connected to a scan line SL and a data line DL, and may transfer a data signal Dm to the driving thin-film transistor T1 according to a scan signal Sn. The data signal Dm may be input through the data line DL, and the scan signal Sn may be input through the scan line SL.

The storage capacitor Cst may be connected to the switching thin-film transistor T2 and a driving voltage line PL and may store a voltage corresponding to a difference between a voltage transferred from the switching thin-film transistor T2 and a driving voltage ELVDD supplied to the driving voltage line PL.

The driving thin-film transistor T1 may be connected to the driving voltage line PL and the storage capacitor Cst and may control a driving current according to the voltage stored in the storage capacitor Cst. For example, the driving current may flow from the driving voltage line PL to the light-emitting element ED. The light-emitting element ED may emit light having a certain brightness corresponding to the driving current.

Though it is described with reference to FIG. 3 that the pixel circuit PC includes two thin-film transistors and one storage capacitor, embodiments are not limited thereto.

Referring to FIG. 4, the pixel circuit PC may include the driving thin-film transistor T1, the switching thin-film transistor T2, a compensation thin-film transistor T3, a first initialization thin-film transistor T4, an operation control thin-film transistor T5, an emission control thin-film transistor T6, and a second initialization thin-film transistor T7.

Although it is shown in FIG. 4 that each pixel circuit PC includes signal lines SL, SL−1, SL+1, EL, and DL, an initialization voltage line VL, and the driving voltage line PL, embodiments are not limited thereto. In another example, at least one of the signal lines SL, SL−1, SL+1, EL, and DL, and/or the initialization voltage line VL may be shared by adjacent pixel circuits PC.

A drain electrode of the driving thin-film transistor T1 may be electrically connected to the light-emitting element ED through the emission control thin-film transistor T6. The driving thin-film transistor T1 may receive a data signal Dm and may supply a driving current to the light-emitting element ED according to a switching operation of the switching thin-film transistor T2.

A gate electrode of the switching thin-film transistor T2 may be connected to the scan line SL, and a source electrode of the switching thin-film transistor T2 may be connected to the data line DL. A drain electrode of the switching thin-film transistor T2 may be connected to the source electrode of the driving thin-film transistor T1, and simultaneously connected to the driving voltage line PL through the operation control thin-film transistor T5.

The switching thin-film transistor T2 may be turned on according to a scan signal Sn transferred through the scan line SL and may perform a switching operation of transferring a data signal Dm to the source electrode of the driving thin-film transistor T1. The data signal Dm may be transferred to the data line DL.

A gate electrode of the compensation thin-film transistor T3 may be connected to the scan line SL. A source electrode of the compensation thin-film transistor T3 may be connected to the drain electrode of the driving thin-film transistor T1, and simultaneously, connected to the pixel electrode of the light-emitting element ED through the emission control thin-film transistor T6. A drain electrode of the compensation thin-film transistor T3 may be connected to one of electrodes of the storage capacitor Cst, a source electrode of the first initialization thin-film transistor T4, and the gate electrode of the driving thin-film transistor T1. The compensation thin-film transistor T3 may be turned on according to a scan signal Sn transferred through the scan line SL such that the driving thin-film transistor T1 may be diode-connected by connecting the gate electrode to the drain electrode of the driving thin-film transistor T1.

A gate electrode of the first initialization thin-film transistor T4 may be connected to the previous scan line SL-1. A drain electrode of the first initialization thin-film transistor T4 may be connected to the initialization voltage line VL. A source electrode of the first initialization thin-film transistor T4 may be connected to one of the electrodes of the storage capacitor Cst, a drain electrode of the compensation thin-film transistor T3, and the gate electrode of the driving thin-film transistor T1. The first initialization thin-film transistor T4 may be turned on according to a previous scan signal Sn−1 received through the previous scan line SL−1 and may perform an initialization operation of initializing the voltage of the gate electrode of the driving thin-film transistor T1 by transferring an initialization voltage Vint to the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 may be connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the light-emitting element ED. The operation control thin-film transistor T5 and the emission control thin-film transistor T6 may be simultaneously turned on according to an emission control signal En transferred through the emission control line EL, and the driving voltage ELVDD may be transferred to the light-emitting element ED, and thus, the driving current may flow through the light-emitting element ED.

A gate electrode of the second initialization thin-film transistor T7 may be connected to the next scan line SL+1. A source electrode of the second initialization thin-film transistor T7 may be connected to the pixel electrode of the light-emitting element ED. A drain electrode of the second initialization thin-film transistor T7 may be connected to the initialization voltage line VL. The second initialization thin-film transistor T7 may be turned on according to a next scan signal Sn+1 transferred through the next scan line SL+1 and may initialize the pixel electrode of the light-emitting element ED.

Although it is shown in FIG. 4 that the first initialization thin-film transistor T4 and the second initialization thin-film transistor T7 are respectively connected to the previous scan line SL-1 and the next scan line SL+1, embodiments are not limited thereto. In another example, both the first initialization thin-film transistor T4 and the second initialization thin-film transistor T7 may be connected to the previous scan line SL−1 and thus driven according to a previous scan signal Sn−1.

The other electrode of the storage capacitor Cst may be connected to the driving voltage line PL. One of the electrodes of the storage capacitor Cst may be connected to the gate electrode of the driving thin-film transistor T1, the drain electrode of the compensation thin-film transistor T3, and the source electrode of the first initialization thin-film transistor T4.

An opposite electrode (e.g., a cathode) of the light-emitting element ED may receive a common voltage ELVSS. The light-emitting element ED may emit light by receiving the driving current from the driving thin-film transistor T1.

The pixel circuit PC is not limited to the number of thin-film transistors, the number of storage capacitors, and the circuit design described with reference to FIGS. 3 and 4 and the number of thin-film transistors, the number of storage capacitors, and the circuit design may be variously changed.

FIG. 5A is a schematic cross-sectional view of the display apparatus DP according to an embodiment. FIG. 5B is a schematic perspective view of the support substrate and the substrate shown in FIG. 5A. FIG. 5C is an enlarged schematic backside view of a region A of FIG. 5B.

Referring to FIGS. 5A to 5C, the display apparatus DP may include the display panel 1, an optical functional layer POL, and a cover member CV. For example, the display panel 1 may include a touch electrode layer TS disposed on the thin-film encapsulation layer 60. The touch electrode layer TS may include an electrode pattern layer and be disposed on the thin-film encapsulation layer 60 in the form a panel, or may have a form in which an electrode pattern layer is stacked on the thin-film encapsulation layer 60. The touch electrode layer TS may obtain/detect coordinate information corresponding to an external input, for example, a touch event.

The optical functional layer POL may reduce the reflectivity of light (e.g., external light) incident toward the display apparatus DP from outside, and/or improve the color purity of light emitted from the display apparatus DP. In an embodiment, the optical functional layer POL may include a retarder and/or a polarizer. The retarder may include a film-type retarder or a liquid crystal-type retarder. The retarder may include a λ/2 retarder and/or a λ/4 retarder. The polarizer may include a film-type polarizer or a liquid crystal-type polarizer. The film-type polarizer may include a stretchable synthetic resin film, and the liquid crystal-type polarizer may include liquid crystals arranged in a certain arrangement. Each of the retarder and the polarizer may further include a protective film.

In another example, optical functional layer POL may include a black matrix and color filters. The color filters may be arranged according to colors of pieces of light emitted respectively from the pixels of the display panel 1. The color filters may each include red, green, or blue pigment or dye. In another example, the color filters may each further include quantum dots in addition to the pigment or dye. In another example, some of the color filters may not include pigment or dye, and may include particles (e.g., scatterers) such as titanium oxide.

In another example, the optical functional layer POL may include a destructive interference structure. The destructive interference structure may include a first reflection layer and a second reflection layer respectively disposed on different layers. First-reflected light and second-reflected light respectively reflected by the first reflection layer and the second reflection layer may destructively interfere and thus the reflectivity of external light may be reduced.

An adhesive member may be disposed between the touch electrode layer TS and the optical functional layer POL. For the adhesive member, a general/typical adhesive member may be employed without limitation. The adhesive member may be a pressure sensitive adhesive (PSA).

The cover member CV may be ultra-thin glass (UTG™) or colorless polyimide (CPI). For example, the optical functional layer POL may be disposed on or under the cover member CV. Hereinafter, for convenience of description, the case where the optical functional layer POL is disposed under the cover member CV is described in detail.

A portion of the display panel 1 may be bent to overlap another portion of the display panel 1. As an example, a portion of the display panel 1 corresponding to the substrate 10b arranged in the bent area BA may be bent. For example, portions of the substrate 10b respectively arranged in the first area 1A, the bent area BA, and the second area 2A may be integral with each other.

The support substrate 10a disposed under the substrate 10b may include a first support substrate 10a-1 and a second support substrate 10a-2 that are spaced apart from each other. For example, the first support substrate 10a-1 may be separated from the second support substrate 10a-2 by an opening area 10a-3. For example, a portion of the substrate 10b may be exposed to the outside in the opening area 10a-3. For example, in a plan view, a planar shape of the opening area 10a-3 may be arranged inside the bent area BA or may be the same as the bent area BA.

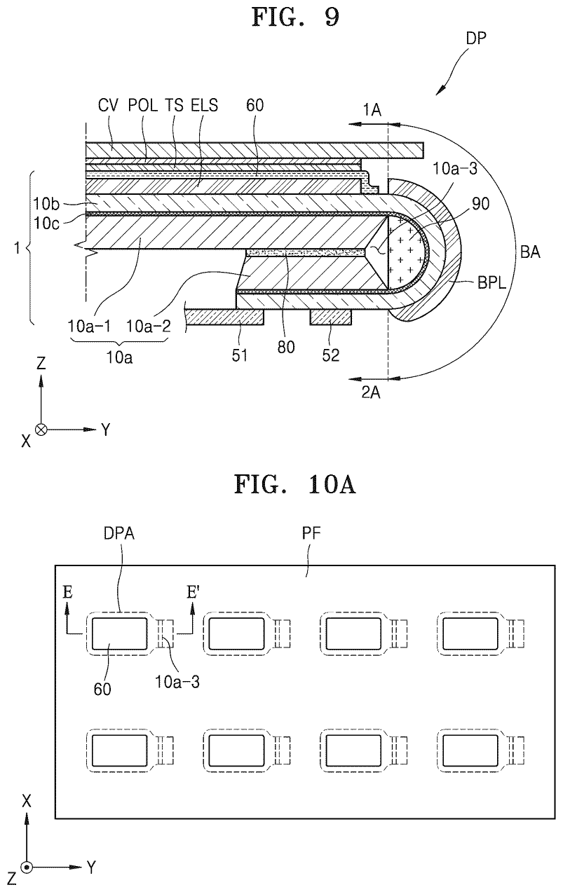

For example, a protective layer may be further disposed between the substrate 10b and the support substrate 10a. For example, the protective layer may be disposed at the same position as the position shown in FIG. 9. For example, the protective layer may include an organic layer that absorbs vibrations transferred from the cutting unit PU in case that the cutting unit PU is used. A protective layer 10c (e.g., see FIG. 9) may include polyimide (PI) or polyamide (PA).

In the case where the display panel 1 is bent, an adhesive member 80 may be disposed on the second support substrate 10a-2. For example, as the first support substrate 10a-1 functions to protect the substrate 10b disposed on the first support substrate 10a-1, the first support substrate 10a-1 may have strength itself. For example, the second support substrate 10a-2 may function to protect the substrate 10b disposed under the second support substrate 10a-2.

At least one of a surface of the first support substrate 10a-1 and a surface of the second support substrate 10a-2 facing each other may include a slope surface. In an embodiment, a side of at least one of the first support substrate 10a-1 and the second support substrate 10a-2 may include a slope surface. As an example, a side adjacent to the opening area 10a-3 among at least one side of the first support substrate 10a-1 and the second support substrate 10a-2 may be a slope surface. Hereinafter, for convenience of description, the case where a side of the first support substrate 10a-1 and a side of the second support substrate 10a-2 adjacent to the opening area 10a-3 slope is described in detail.

The side of the first support substrate 10a-1 and the side of the second support substrate 10a-2 may be slope surfaces that rise (or extend) in a direction away from the opening area 10a-3. For example, referring to FIG. 5A, the thickness of the cross-section of a side of the first support substrate 10a-1 and the thickness of the cross-section of a side of the second support substrate 10a-2 may increase as a distance from the opening area 10a-3 increases.

For example, in at least one of the side of the first support substrate 10a-1 and the side of the second support substrate 10a-2, which are slope surfaces, a groove 10a-4 may be formed in at least one of an edge portion with another surface, a slope surface of the first supporting substrate 10a-1, and a slope surface of the second supporting substrate 10a-2. In an embodiment, one of the surface of the first support substrate 10a-1 and the surface of the second support substrate 10a-2 facing each other may include a groove 10a-4 extending in a direction away from another one of the surface of the first support substrate 10a-1 and the surface of the second support substrate 10a-2 facing each other. As an example, the groove 10a-4 may be formed in an edge portion or a boundary area 10a-1a between the slope surface of the first support substrate 10a-1 and the side of the first support substrate 10a-1 facing the second support substrate 10a-2. In another example, the groove 10a-4 may be formed in an edge portion or a boundary area 10a-2a between the slope surface of the second support substrate 10a-2 and the side of the second support substrate 10a-2 facing the first support substrate 10a-1. In another example, the groove 10a-4 may be formed in an edge portion between the slope surface of the first support substrate 10a-1 and the side of the first support substrate 10a-1 facing the substrate 10b. For example, the groove 10a-4 may be formed in an edge portion between the slope surface of the second support substrate 10a-2 and the surface of the second support substrate 10a-2 facing the substrate 10b. In another example, the groove 10a-4 may be formed in at least one of the slope surface of the first support substrate 10a-1 and the slope surface of the second support substrate 10a-2. For example, the groove 10a-4 may extend to the slope surface of the first support substrate 10a-1 from the edge portion between the side of the first support substrate 10a-1 and the slope surface of the first support substrate 10a-1, and extend to an edge portion between the slope surface of the first support substrate 10a-1 and another side of the first support substrate 10a-1. For example, the slope surface of the first support substrate 10a-1 may connect the side of the first support substrate 10a-1 and the another side of the first support substrate 10a-1 facing each other (or opposite to each other). Hereinafter, for convenience of description, the case where the groove 10a-4 is formed between the side of the first support substrate 10a-1 and the slope surface of the first support substrate 10a-1 is described in detail.

A maximum width of the groove 10a-4 may be greater than 0 μm and may be equal to or less than 50 μm. For example, a maximum width d of the groove 10a-4 measured in a direction (e.g., a Y axis direction of FIG. 5C) from the boundary areas 10a-1a and 10a-2a where two sides meet/intersect each other, and a lower point of the side of the first support substrate 10a-1 and/or the side of the second support substrate 10a-2 may be in a range exceeding 0 μm and equal to or less than 50 μm.

As at least one of the first support substrate 10a-1 and the second support substrate 10a-2 adjacent to the opening area 10a-3 includes a slope surface, in case that the substrate 10b is bent in the bent area BA, a slope surface of the support substrate 10a may be bent together or may vary in shape. For example, although force is applied to the bent area BA after the substrate 10b is bent, the force applied to the bent area BA may be supported through the slope surface of the support substrate 10a.

Although embodiments show that the substrate 10b is bent around the bending axis such that a portion of the lower surface in the first area 1A faces a portion of the lower surface in the second area 2A, embodiments are not limited thereto. As an example, a curvature in the bent area BA may be less than a curvature shown in the drawings, or although a curvature does not drastically change in the bent area BA, the area of the bent area BA may be narrow and a lower surface in the second area 2A may not face a lower surface in the first area 1A. However, various changes may be made.

The first support substrate 10a-1 arranged in a bent side of the substrate 10b may face the second support substrate 10a-2.

For example, the display area DA shown in FIG. 1 may be arranged in the first support substrate 10a-1. For example, in a plan view, the edge portion (or the boundary area) of the display area DA may be arranged inside the edge portion (or the boundary area) of the first support substrate 10a-1. In a plan view, the size of a planar shape of the first support substrate 10a-1 may be greater than the size of a planar shape of the second support substrate 10a-2.

For example, in a plan view, at least a portion of the second support substrate 10a-2 may overlap the display area DA shown in FIG. 1. As an example, in a plan view, at least a portion of the second support substrate 10a-2 may be arranged inside the display area DA. For example, in a plan view, at least a portion of the edge portion (or the boundary area) of the second support substrate 10a-2 may be arranged inside the edge portion (or the boundary area) of the display area DA.

For example, the adhesive member 80 may be disposed on the side of the second support substrate 10a-2, and the adhesive member 80 may fix the second support substrate 10a-2 to the first support substrate 10a-1. For example, the side of the second support substrate 10a-2 may be fixed to the first support substrate 10a-1 through the adhesive member 80, and another side of the second support substrate 10a-2 may be fixed (e.g., directly fixed) to the substrate 10b without a separate adhesive member.

For example, a separate protective member may be disposed between the first support substrate 10a-1 and the second support substrate 10a-2. The protective member may include polymer resin such as polyurethane, polycarbonate, polypropylene, polyethylene, and the like, or rubber, urethane-based materials, epoxy-based materials, acrylic-based materials, or resins in combination thereof may be disposed and cured on the first support substrate 10a-1 and the second support substrate 10a-2 and fill the protective member. In another example, the protective member may be disposed in the form of a sheet including an elastic material such as sponge molded by foaming rubber, urethane-based materials, epoxy-based or acrylic-based materials.

The protective member may be disposed between the first support substrate 10a-1 and the second support substrate 10a-2 and may prevent the first support substrate 10a-1 from colliding with the second support substrate 10a-2.

The display panel 1 may include a bending protective layer BPL arranged in the bent area BA. For example, the bending protective layer BPL may be arranged in the bent portion or bent area BA of the substrate 10b and may prevent the substrate 10b from being destroyed/broke in case that the substrate 10b is bent. The bending protective layer BPL may include polymer resin such as polyethyleneterephthalate (PET) and polyimide (PI). The bending protective layer BPL may have a greater planar shape than the bent area BA shown in FIG. 1. For example, in a plan view, the bent area BA may be arranged inside the bending protective layer BPL. For example, in a plan view, the opening area 10a-3 may be arranged inside the bending protective layer BPL.

Accordingly, the display apparatus DP may partially increase strength of the bent area BA.

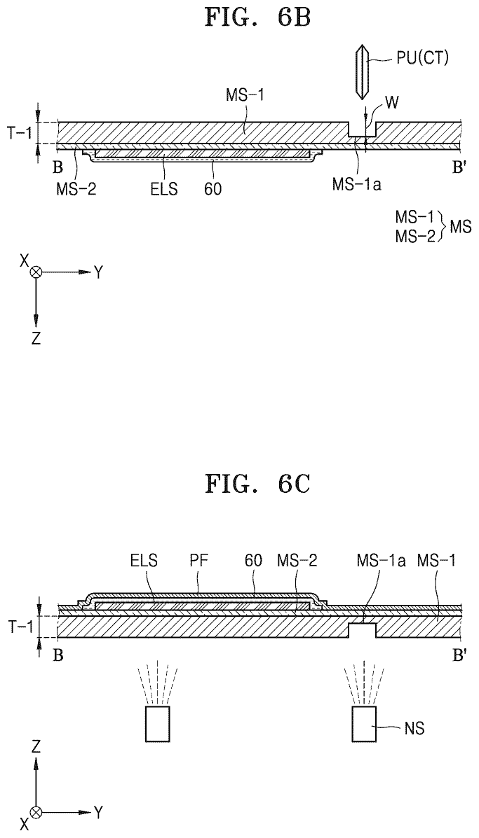

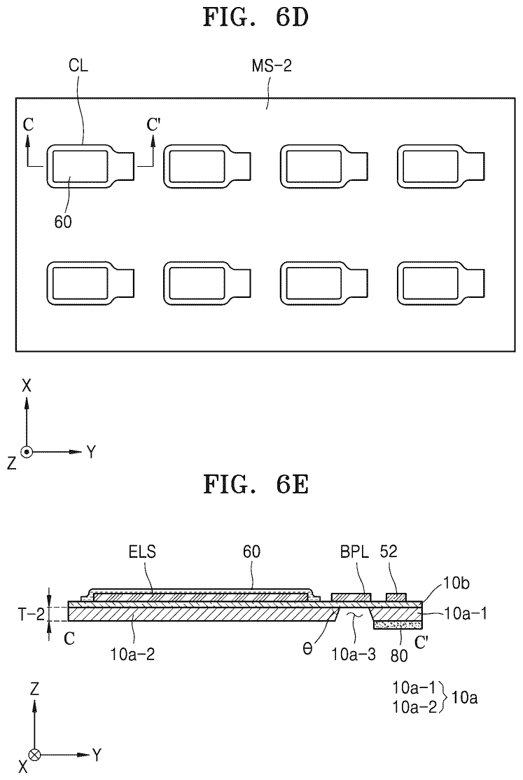

FIG. 6A is a schematic plan view showing manufacturing of the display apparatus DP according to an embodiment. FIG. 6B is a schematic cross-sectional view showing manufacturing of the display apparatus DP taken along line B-B′ of FIG. 6A according to an embodiment.

Referring to FIGS. 6A and 6B, a base substrate MS may include a first base substrate MS-1 and a second base substrate MS-2. The first base substrate MS-1 may be prepared, and the second base substrate MS-2, a display portion ELS, and the thin-film encapsulation layer 60 may be disposed or formed on the first base substrate MS-1. For example, the first base substrate MS-1 and the support substrate 10a may include the same material, and the second base substrate MS-2 and the substrate 10b may include the same material. For example, the second base substrate MS-2 may be disposed on the front surface of the first base substrate MS-1 or disposed on only a portion of the first base substrate MS-1. The first base substrate MS-1 may have a first thickness T-1. Hereinafter, for convenience of description, the case where the second base substrate MS-2 is disposed on the first base substrate MS-1 is described in detail.

At least one display portion ELS may be disposed on the second base substrate MS-2. In the case where display portions ELS are provided, the display portions ELS may be disposed to be spaced apart from each other on the second base substrate MS-2. In another example, in the case where the substrate 10b is provided in plurality, the substrates 10b are disposed to be spaced apart from each other. For example, the display portion ELS may be provided in plurality, and each display portion ELS may be disposed on each substrate 10b. For example, the thin-film encapsulation layer 60 may be disposed on each display portion ELS. For example, the thin-film encapsulation layer 60 may be disposed to shield each display portion ELS completely and be disposed in plurality to be spaced apart from each other. Each thin-film encapsulation layer 60 may be disposed to correspond to each display portion ELS. Hereinafter, for convenience of description, the case where one second base substrate MS-2 is disposed on the first base substrate MS-1, and each display portion ELS and each thin-film encapsulation layer 60 are disposed on the second base substrate MS-2 is described in detail.

A reference groove MS-la may be formed in the first base substrate MS-1. For example, the reference groove MS-la may be formed in a portion of a panel area DPA corresponding to the opening area 10a-3. For example, in a plan view, a planar shape of the reference groove MS-la may be arranged inside a planar shape of the opening area 10a-3.

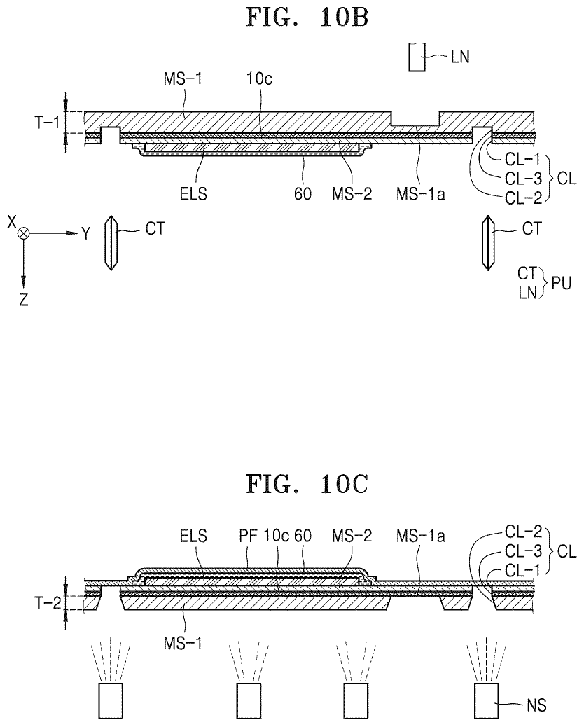

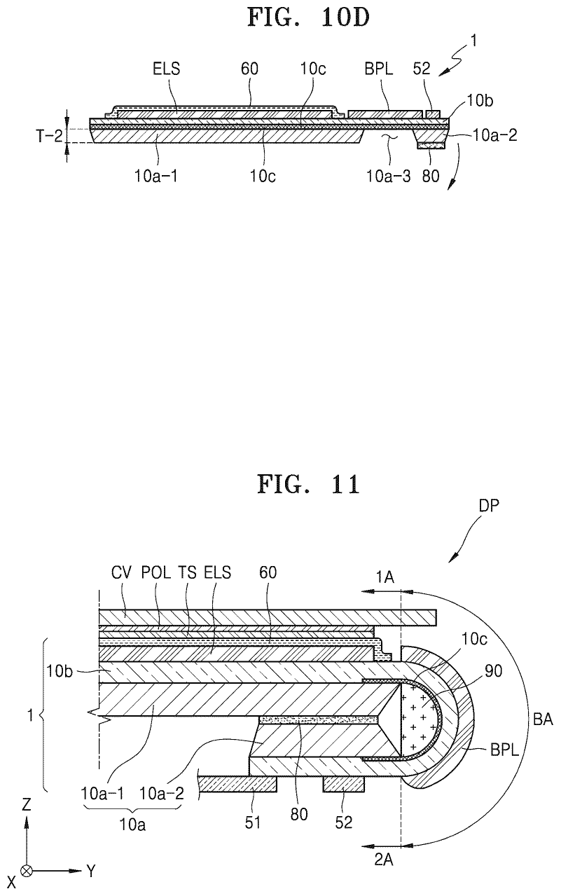

The reference groove MS-la may be formed by using a cutting unit PU. For example, the cutting unit PU may include a cutter CT that physically forms the reference groove MS-1a, such as a blade, or a laser irradiator LN (e.g., see FIG. 10B) that forms the reference groove MS-la by irradiating a laser beam. Hereinafter, for convenience of description, the case where the cutting unit PU includes a cutter CT is described in detail.

The reference groove MS-la may have a depth W measured from a side of the first base substrate MS-1. For example, the depth W may have linear relationship with a taper angle θ (see FIG. 6E) of a slope surface (e.g., a surface of the first base substrate MS-1 disposed around the opening area 10a-3). As an example, the depth W and the taper angle θ may have a relationship represented by Equation 1 below. For example, the taper angle θ may denote an angle between a side of the first base substrate MS-1 contacting the second base substrate MS-2, and a slope surface of the first base substrate MS-1.

Y=0.1838X+5.2766 [Equation 1]

Here, Y denotes the taper angle θ, its unit is degree)(°, X denotes the depth W, and its unit is micrometer (μm). For example, the unit of 0.1838 may be degree(°/μm, and the unit of 5.2766 may be degree(°).

A groove may be formed in a portion of the reference groove MS-la. As an example, a groove may be formed in an entry portion of the reference groove MS-la formed in a side of the first base substrate MS-1 on which the second base substrate MS-2 is not disposed.

FIG. 6C is a schematic cross-sectional view showing manufacturing of the display apparatus DP taken along line B-B′ of FIG. 6A according to an embodiment.

Referring to FIG. 6C, the reference groove MS-la may be formed, and a protective film PF in the form of an etching protective layer may be disposed or attached on the display portion ELS and the thin-film encapsulation layer 60. For example, the protective film PF may be attached to the entire surface of the first base substrate MS-1 or attached to only a portion of the first base substrate MS-1 on which the thin-film encapsulation layer 60 is disposed. The protective film PF may have heat resistance and chemical resistance.

For example, an etching solution may be sprayed on a side of the first base substrate MS-1 on which the second base substrate MS-2 is not disposed, through a nozzle NS. The etching solution may reach the first base substrate MS-1 in the outside and etch the side of the first base substrate MS-1. Thus, the side of the first base substrate MS-1 may be isotropically etched, and the reference groove MS-la may expand to form the opening area 10a-3. For example, the side of the first base substrate MS-1 adjacent to the opening area 10a-3 may be formed to be a slope surface. For example, the groove may be formed in the boundary area of the slope surface as shown in FIG. 5C. In another example, the groove may be completely removed from the boundary area of the slope surface.

FIG. 6D is a schematic plan view showing manufacturing of the display apparatus DP according to an embodiment. Referring to FIG. 6D, the first base substrate MS-1 and the second base substrate MS-2 may be separated in plurality through a cutting line CL. In an embodiment, the first base substrate MS-1 and the second base substrate MS-2 may be cut along a cutting line CL spaced apart from an edge portion of the display layer and the thin-film encapsulation layer 60. For example, there may be various methods of separating the first base substrate MS-1 and the second base substrate MS-2 by using the cutting line CL. In an embodiment, the first base substrate MS-1 and the second base substrate MS-2 may be separated into display panels 1 by irradiating a laser beam to the first base substrate MS-1 and the second base substrate MS-2 along the cutting line CL or separating the first base substrate MS-1 and the second base substrate MS-2 through the cutter CT. In another example, the second base substrate MS-2 may be separated into a plurality of pieces through the cutter CT, and a separate protective film may be attached to the inside of the cutting line CL of the first base substrate MS-1, and the first base substrate MS-1 may be separated into a plurality of pieces along the cutting line CL through an etching process. For example, as described above, the method of separating the first base substrate MS-1 may be performed separately from or simultaneously with the process shown in FIGS. 6B and 6C.

In the case where the first base substrate MS-1 and the second base substrate MS-2 are separated along the cutting line CL, the first base substrate MS-1 may be divided into a plurality of pieces to form the display panel 1 (e.g., a single display panel). For example, the display panel 1 may include the substrate 10b, and the first support substrate 10a-1 and the second support substrate 10a-2 may be disposed under the substrate 10b. The first support substrate 10a-1 may be separated from the second support substrate 10a-2 by the opening area 10a-3.

FIG. 6E is a schematic cross-sectional view showing manufacturing of the display apparatus DP taken along line C-C′ of FIG. 6D according to an embodiment.

Referring to FIG. 6E, the adhesive member 80 may be disposed on the second support substrate 10a-2. For example, the second support substrate 10a-2 may be attached to the first support substrate 10a-1 by using the adhesive member 80 by bending a portion of the substrate 10b on which the second support substrate 10a-2 is disposed.

The thickness of the support substrate 10a may be a second thickness T-2. For example, the second thickness T-2 may be less than the first thickness T-1 described above.

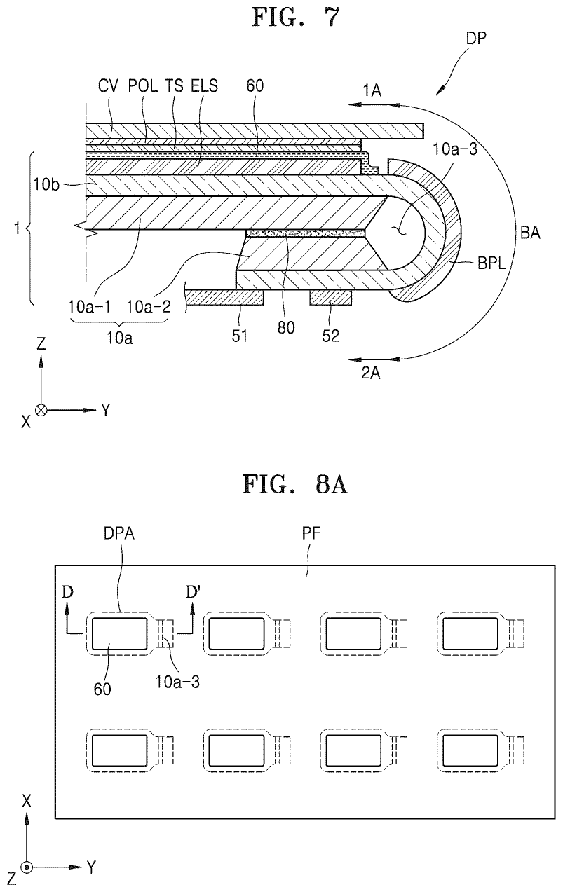

FIG. 7 is a schematic cross-sectional view of the display apparatus DP according to an embodiment. Hereinafter, the same reference numerals as those of FIG. 5A represent the same members.

Referring to FIG. 7, the display apparatus DP may include the display panel 1, the display circuit board 51, the display driver 52, the touch sensor driver, the optical functional layer POL, and the cover member CV. For example, the display panel 1 may include the support substrate 10a, the substrate 10b, the display portion ELS, and the touch electrode layer TS disposed on the thin-film encapsulation layer 60. For example, as the display panel 1 is the same as or similar to that described with reference to FIGS. 1, 2 and 5A to 5C, detailed description is omitted for descriptive convenience.

The support substrate 10a may include the first support substrate 10a-1 and the second support substrate 10a-2 arranged to be spaced apart from each other around the opening area 10a-3. For example, a side of the first support substrate 10a-1 and a side of the second support substrate 10a-2 adjacent to the opening area 10a-3 may be slope surfaces.

At least one of surfaces forming the edge portion of the first support substrate 10a-1 may be a slope surface. For example, at least one of surfaces forming the edge portion of the second support substrate 10a-2 may be a slope surface. As an example, at least one of two opposite sides (e.g., sides arranged in long sides of the first support substrate 10a-1) arranged in an X axis direction of the first support substrate 10a-1 and two opposite sides (e.g., sides arranged in short sides of the first support substrate 10a-1) arranged in a Y axis direction of the first support substrate 10a-1 arranged in the first area 1A in FIG. 1 may be a slope surface. For example, one of the two opposite sides arranged in the short sides of the first support substrate 10a-1 may be a surface adjacent to the opening area 10a-3. For example, at least one of two opposite sides (e.g., sides arranged in short sides of the second support substrate 10a-2) arranged in an X axis direction of the second support substrate 10a-2 and two opposite sides (e.g., sides arranged in long sides of the second support substrate 10a-2) arranged in a Y axis direction of the second support substrate 10a-2 arranged in the second area 2A may be a slope surface. For example, one of the two opposite sides arranged in the short sides of the second support substrate 10a-2 may be a surface adjacent to the opening area 10a-3. Hereinafter, for convenience of description, the case where the side arranged in the long side of the second support substrate 10a-2 is a slope surface is described in detail.

For example, two opposite sides arranged in the long sides of the second support substrate 10a-2 may be slope surfaces. For example, the groove described above may be formed in the boundary area between one of the two opposite sides arranged in the long sides of the second support substrate 10a-2, and a side of the second support substrate 10a-2 on which the adhesive member 80 is disposed.

Accordingly, the display apparatus DP may partially increase strength of the bent area BA.

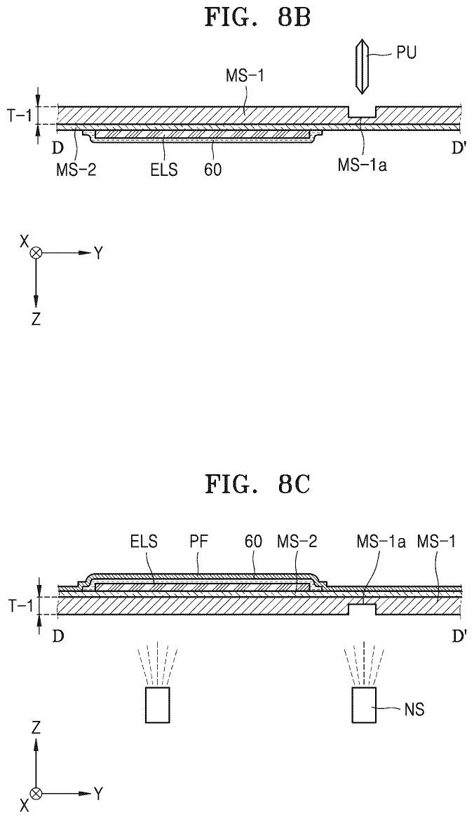

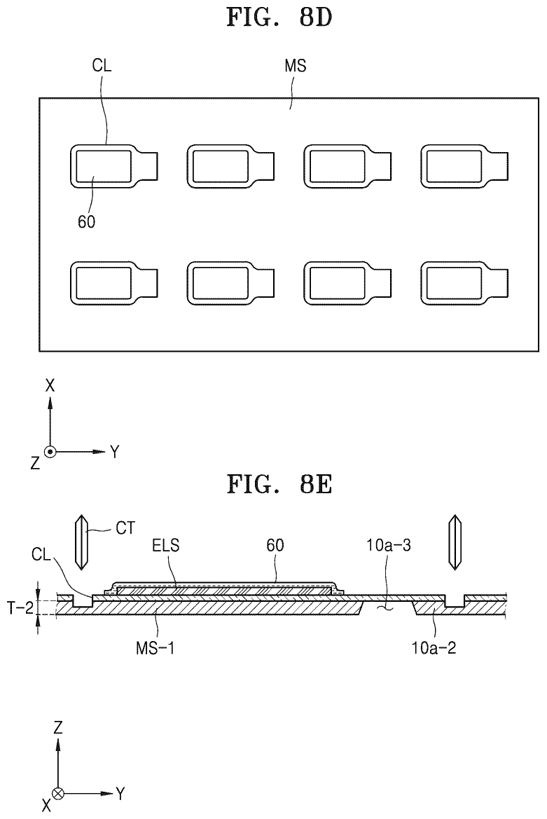

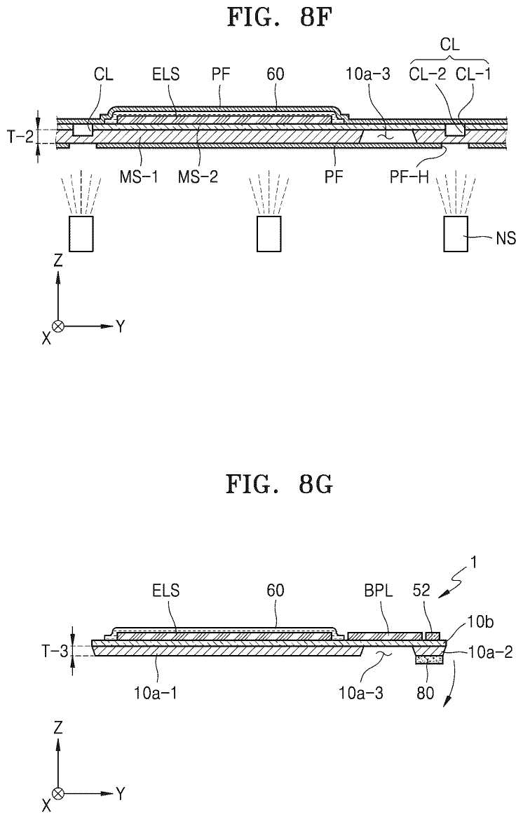

FIG. 8A is a schematic plan view showing manufacturing of the display apparatus DP according to an embodiment. FIG. 8B is a schematic cross-sectional view showing manufacturing of the display apparatus DP taken along line D-D′ of FIG. 8A according to an embodiment. Referring to FIGS. 8A and 8B, the second base substrate MS-2 may be disposed on the entire surface of the first base substrate MS-1, or substrates 10b arranged to be spaced apart from each other may be formed. For example, each substrate 10b may be arranged to correspond to the panel area DPA. The panel areas DPA may be separated from each other afterward and may each form a single display panel 1.

Hereinafter, for convenience of description, the case where the second base substrate MS-2 is disposed on the entire surface of the first base substrate MS-1 is described in detail.

The display portion ELS and the thin-film encapsulation layer 60 may be disposed on the second base substrate MS-2, and the reference groove MS-la may be formed in the first base substrate MS-1 by using the cutting unit PU. For example, the reference groove MS-1a may be formed in a side of the first base substrate MS-1 on which the display portion ELS is not disposed. The thickness of the first base substrate MS-1 may be the first thickness T-1.

FIG. 8C is a schematic cross-sectional view showing manufacturing of the display apparatus DP taken along line D-D′ of FIG. 8A according to another embodiment.

Referring to FIG. 8C, the protective film PF may be disposed on the thin-film encapsulation layer 60. For example, as the protective film PF is the same as or similar to that described with reference to FIG. 6C, detailed description thereof is omitted for descriptive convenience.

An etching solution may be sprayed (e.g., entirely sprayed) on/to a side of the first base substrate MS-1 in which the reference groove MS-la is formed, through the nozzle NS. For example, the etching solution may isotropically or entirely etch the surface of the first base substrate MS-1. For example, the etching solution may expand the reference groove MS-la, and the opening area 10a-3 may be formed in the first base substrate MS-1.

For example, in the case where the etching solution is sprayed, the size of the opening area 10a-3 may be formed less than a designed size.

In the case where the etching solution is sprayed on/to the first base substrate MS-1, the thickness of the first base substrate MS-1 may be a second thickness T-2 as shown in FIG. 8E. For example, the second thickness T-2 may be less than the first thickness T-1.

FIG. 8D is a schematic plan view showing manufacturing of the display apparatus DP according to an embodiment. FIG. 8E is a schematic cross-sectional view showing manufacturing of the display apparatus DP according to an embodiment.

Referring to FIGS. 8D and 8E, the cutting line CL may be formed in the second base substrate MS-2 and the first base substrate MS-1. For example, the cutting line CL may be formed by using the cutter CT. For example, a cutting groove or cutting line hole CL-1 (e.g., see FIG. 8F) may be formed in the second base substrate MS-2, and a cutting line groove CL-2 (e.g., see FIG. 8F) may be formed in the first base substrate MS-1. For example, the cutting line hole CL-1 may be connected to the cutting line groove CL-2.

For example, the cutter CT may cut the first base substrate MS-1 and the second base substrate MS-2 along the cutting line CL instead of forming the cutting line hole CL-1 and the cutting line groove CL-2. For example, the display panel 1 may be separated from the first base substrate MS-1 and the second base substrate MS-2 and the process may be finished.

Hereinafter, for convenience of description, the case where the cutter CT forms the cutting line hole CL-1 and the cutting line groove CL-2 is described in detail.

FIG. 8F is a schematic cross-sectional view showing manufacturing of the display apparatus DP according to an embodiment.

Referring to FIG. 8F, the cutting line CL may be formed, and the protective film PF may be disposed on the thin-film encapsulation layer 60. For example, the protective film PF may be the same as or similar to that described above.

A protective film hole of the protective film PF may be formed to correspond to the cutting line CL. In another example, the protective film PF may be disposed to cover the cutting line CL. Hereinafter, for convenience of description, the case where the protective film PF is disposed to cover the cutting line CL is described in detail.

The protective film PF may be disposed on a side of the first base substrate MS-1 in which the opening area 10a-3 is arranged. For example, a protective film hole PF-H may be formed in a portion of the protective film PF corresponding to the cutting line CL.

In case that the above process is completed, an etching solution may be sprayed on/to a side of the first base substrate MS-1 on which the display portion ELS is not disposed, through the nozzle NS. For example, as the etching solution etches the side of the first base substrate MS-1, a hole connected to the cutting line CL may be formed.

For example, a separate protective film may not be disposed on an entire side of the first support substrate 10a-1 on which the display portion ELS is not disposed except for the cutting line CL.

FIG. 8G is a schematic cross-sectional view showing manufacturing of the display apparatus DP according to another embodiment.

Referring to FIG. 8G, the display panel 1 may be separated from the first base substrate MS-1 and the second base substrate MS-2 through the cutting line CL. For example, at least one of sides of the second support substrate 10a-2 of the display panel 1 may slope. For example, a slope direction of a side of the second support substrate 10a-2 adjacent to the opening area 10a-3 may be opposite to a slope direction of another side. As an example, referring to the cross-section of FIG. 8G, a side of the second support substrate 10a-2 adjacent to the opening area 10a-3 may lower as being closer to the right from the left, in case that a side of the second support substrate 10a-2 disposed on the end portion may lower as being closer to the left from the right. For example, the thickness T-3 of the first support substrate 10a-1 (or the second support substrate 10a-2) in FIG. 8G may be less than the second thickness T-2 of the first base substrate MS-1 in FIGS. 8E and 8F.

FIG. 9 is a schematic cross-sectional view of the display apparatus DP according to an embodiment. Hereinafter, the same reference numerals as those of FIG. 5A represent the same members.

Referring to FIG. 9, the display apparatus DP may include the display panel 1, the display circuit board 51, the display driver 52, the touch sensor driver, the optical functional layer POL, and the cover member CV. For example, the display panel 1 may include the support substrate 10a, the substrate 10b, the display portion ELS, and the touch electrode layer TS disposed on the thin-film encapsulation layer 60. For example, as the display panel 1 is similar to that described with reference to FIGS. 1, 2 and 5A to 5C, detailed description is omitted for descriptive convenience.

The display panel 1 may include the protective layer 10c disposed between the support substrate 10a and the substrate 10b. In the case where a laser beam is irradiated, the protective layer 10c may reduce transmission of the laser beam to the display portion ELS or reduce transmission of heat generated by the laser beam to the display portion ELS. The protective layer 10c may include an inorganic layer. As an example, the protective layer 10c may include amorphous silicon, silicon oxide (SiOₓ) and/or silicon nitride (SiNₓ).

In a plan view, the protective layer 10c may be arranged to overlap at least a portion of the substrate 10b. Hereinafter, for convenience of description, the case where the protective layer 10c is disposed on the entire surface of the substrate 10b is described in detail.

For example, the display panel 1 may include a filler 90 arranged in the bent area of the substrate 10b. For example, the filler 90 may include an elastic material and maintain bending of the substrate 10b in case that the substrate 10b is bent. For example, in the case where external force is applied to the bent area, the filler 90 may prevent the substrate 10b in the bent area from being destroyed by absorbing impacts. For example, the filler 90 may be disposed to fill at least a portion of a space formed by the first support substrate 10a-1, the second support substrate 10a-2, the adhesive member 80, and the substrate 10b.

FIG. 10A is a schematic plan view showing manufacturing of the display apparatus DP according to an embodiment. FIG. 10B is a schematic cross-sectional view showing manufacturing of the display apparatus DP taken along line E-E′ of FIG. 10A according to an embodiment.

Referring to FIGS. 10A and 10B, the first base substrate MS-1, the protective layer 10c, and the second base substrate MS-2 may be sequentially stacked, and the display portion ELS and the thin-film encapsulation layer 60 may be disposed on the second base substrate MS-2.

For example, the reference groove MS-la and the cutting line CL may be formed. For example, the reference groove MS-la and the cutting line CL may be formed by using a cutter CT or a laser irradiator LN. For example, in the case where the cutting line CL is formed by using the laser irradiator LN, the protective layer 10c may not be arranged in a portion in which the cutting line CL is formed. For example, as the protective layer 10c is arranged in only the panel area DPA, a plurality of protective layers 10c may be arranged to be spaced apart from each other like the panel areas DPA. In another example, in the case where the cutting line CL is formed by using the cutter CT, the protective layer 10c may be formed on the entire surface of the first base substrate MS-1. For example, the cutting line CL may include a first cutting line hole CL-1 formed in the second base substrate MS-2, a second cutting line groove CL-2 formed in the first base substrate MS-1, and a third cutting line hole CL-3 formed in the protective layer 10c. Hereinafter, for convenience of description, the case where the protective layer 10c is formed on the entire surface of the first base substrate MS-1 and the cutting unit PU includes the cutter CT is described in detail.

The thickness of the first base substrate MS-1 may be the first thickness T-1.

FIG. 10C is a schematic cross-sectional view showing manufacturing of the display apparatus DP taken along line E-E′ of FIG. 10A according to an embodiment.

Referring to FIG. 10C, the cutting line CL and the reference groove MS-la may be formed, and the protective film PF may be disposed on the second base substrate MS-2 on which the cutting line CL is disposed. For example, the protective film PF may be disposed on the entire surface of the first base substrate MS-1 to cover the cutting line CL.

For example, an etching solution may be sprayed on/to a side of the first base substrate MS-1 on which the second base substrate MS-2 is not disposed, through the nozzle NS. For example, a side of the first base substrate MS-1 may be etched, and the reference groove MS-la may expand to form the opening area 10a-3. For example, as a portion of the first base substrate MS-1 on which the cutting line CL is disposed is etched and connected to the cutting line CL, the panel area DPA (see FIG. 10A) may be separated from the first base substrate MS-1 and the second base substrate MS-2. For example, a portion of the outer surface of the display panel 1 cut along the cutting line CL may slope, and a portion of the outer surface may be a straight line. For example, the cutting line CL may include the first cutting line hole CL-1 formed in the second base substrate MS-2, the second cutting line groove CL-2 formed in the first base substrate MS-1, and the third cutting line hole CL-3 formed in the protective layer 10c. For example, the thickness of the first base substrate MS-1 may be the second thickness T-2. For example, the second thickness T-2 may be less than the first thickness T-1.

FIG. 10D is a schematic cross-sectional view showing manufacturing of the display apparatus DP taken along line E-E′ of FIG. 10A according to another embodiment.

Referring to FIG. 10D, the display panel 1 separated from the first base substrate MS-1 and the second base substrate MS-2 may be bent. For example, the adhesive member 80 may be disposed on the second support substrate 10a-2, and the first support substrate 10a-1 may be attached to the second support substrate 10a-2 by bending the bent area of the substrate 10b. For example, the adhesive member 80 may be attached to the first support substrate 10a-1 first, and then attached to the second support substrate 10a-2. For example, the bending protective layer BPL may be arranged in the bent area, and the display driver 52 may be arranged in the second area 2A. In an embodiment, the second base substrate MS-2 may be bent around an arbitrary bending axis overlapping the bending protective layer BPL.

FIG. 11 is a schematic cross-sectional view of the display apparatus DP according to an embodiment. Hereinafter, the same reference numerals as those of FIG. 5A represent the same members.

Referring to FIG. 11, the display apparatus DP may include the display panel 1, the display circuit board 51, the display driver 52, the touch sensor driver, the optical functional layer POL, and the cover member CV. For example, the display panel 1 may include the support substrate 10a, the substrate 10b, the display portion ELS, and the touch electrode layer TS disposed on the thin-film encapsulation layer 60. For example, as the display apparatus DP and the display panel 1 are similar to those described with reference to FIGS. 1, 2 and 5A to 5C, detailed descriptions thereof are omitted for descriptive convenience.

The display panel 1 may include the protective layer 10c disposed between the support substrate 10a and the substrate 10b. For example, the protective layer 10c may be disposed on only a portion of the substrate 10b. As an example, in a plan view, the protective layer 10c may be arranged to overlap the bent area BA. For example, in a plan view, the reference groove may be formed inside the protective layer 10c in FIGS. 10B, and 10C.

The protective layer 10c may prevent the display portion ELS arranged around the reference groove from being damaged in case that the reference groove is formed through the laser beam.

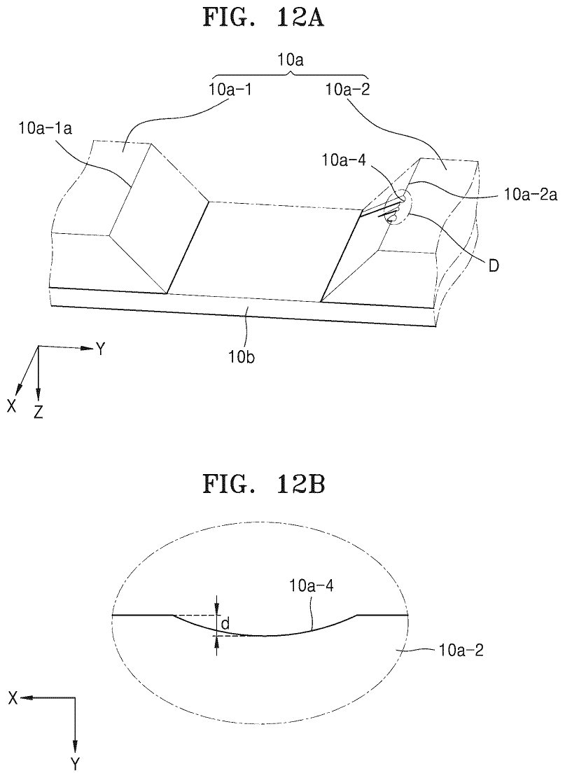

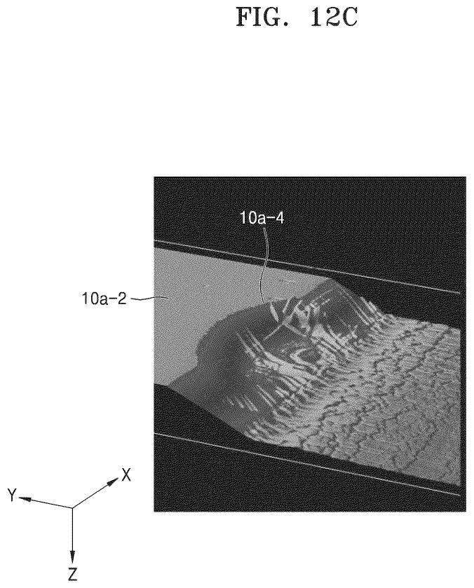

FIG. 12A is a schematic perspective view of a portion of a display apparatus according to an embodiment, FIG. 12B is an enlarged schematic backside view of a region D of FIG. 12A, FIG. 12C is a schematic perspective view of a portion shown in FIG. 12A, and FIG. 12D is a schematic cross-sectional view of an opening area shown in FIG. 12A.

Referring to FIG. 12A, the display apparatus DP may include a display panel, a display circuit board, a display driver, a touch sensor driver, an optical functional layer, and a cover member. For example, the display panel may include the support substrate 10a, the substrate 10b, a display portion, a touch electrode layer disposed on a thin-film encapsulation layer. For example, as the display apparatus and the display panel are similar to those described with reference to FIGS. 1, 2, and 5A to 5C, detailed descriptions thereof are omitted for descriptive convenience.

For example, the support substrate 10a may include the first support substrate 10a-1 and the second support substrate 10a-2. For example, as the first support substrate 10a-1 and the second support substrate 10a-2 are the same as or similar to those described with reference to FIGS. 1, 2, and 5A to 5C, detailed descriptions thereof are omitted for descriptive convenience.

At least one of the slope surface of the first support substrate 10a-1 and the slope surface of the second support substrate 10a-2 may include the groove 10a-4. The groove 10a-4 may be disposed in at least one of a boundary area 10a-1a between a slope surface of the first support substrate 10a-1 and a surface of the first support substrate 10a-1, and a boundary area 10a-2a between a slope surface of the second support substrate 10a-2 and a surface of the second support substrate 10a-2. As the case where the groove 10a-4 is formed in the slope surface of the first support substrate 10a-1 and the case where the groove 10a-4 is formed in the slope surface of the second support substrate 10a-2 are similar to each other, the case where the groove 10a-4 is formed in the slope surface of the first support substrate 10a-1 is described below in detail, for convenience of description.

In the case where the groove 10a-4 is disposed in the boundary area 10a-1a between the slope surface of the first support substrate 10a-1 and a surface of the first support substrate 10a-1, the groove 10a-4 may extend to the slope surface of the first support substrate 10a-1. For example, the groove 10a-4 may be disposed in only a portion of the slope surface of the first support substrate 10a-1, or may extend from one of the boundaries of the slope surface of the first support substrate 10a-1 to another one of the boundaries of the slope surface of the first support substrate 10a-1. For example, the groove 10a-4 may be formed in a line shape in the slope surface of the first support substrate 10a-1. For example, the width of the groove 10a-4 may be constant in a lengthwise direction of the groove 10a-4. In another example, the width of the groove 10a-4 may vary in the slope surface of the first support substrate 10a-1. For example, the width of the groove 10a-4 may be reduced in the lengthwise direction of the groove 10a-4 in the slope surface of the first support substrate 10a-1. For example, the width of the groove 10a-4 may be reduced as being closer to the substrate 10b from the surface of the first support substrate 10a-1. In another example, the groove 10a-4 may be a portion of a sphere. In another example, the groove 10a-4 may have an ellipsoidal shape. In another example, the groove 10a-4 may have an irregular shape. Hereinafter, for convenience of description, the case where the groove 10a-4 is a portion of a sphere is described in detail.

Referring to FIGS. 12C and 12D, a cross-section (e.g., a cross-section taken along a Z-Y plane in FIG. 12A) of a surface of the support substrate defining the groove 10a-4 may be round. For example, the cross-section of a surface of the support substrate defining the groove 10a-4 may be formed in various shapes. In an embodiment, the cross-section of the surface of the support substrate defining the groove 10a-4 may have a round shape. In another example, the cross-section of the surface of the support substrate defining the groove 10a-4 may be formed to have a step difference in a thickness direction of the support substrate 10a. For example, the cross-section of a surface of the support substrate defining the groove 10a-4 may have at least two different surfaces. As an example, the cross-section of the surface of the support substrate defining the groove 10a-4 may be variable in its shape with respect to a surface of the support substrate 10a around a point. For example, around the point of the cross-section of the surface of the groove 10a-4, slope surfaces of two opposite sides of the cross-section of the surface of the support substrate defining the groove 10a-4 may be connected to each other although they have different shapes. At least one point where the shape is variable may be provided on the cross section of the surface of the support substrate defining the groove 10a-4. In another example, the cross section of the surface of the support substrate defining the groove 10a-4 may include irregularities. For example, the cross-section of the surface of the groove 10a-4 may have an uneven shape.

The groove 10a-4 formed in the boundary area 10a-1a between the slope surface of the first support substrate 10a-1 and a surface of the first support substrate 10a-1 may have a certain depth DT from the surface of the first support substrate 10a-1. For example, the depth DT of the groove 10a-4 may be proportional to a maximum width d of the groove 10a-4 formed in the surface of the first support substrate 10a-1. Thus, in case that the maximum width d of the groove 10a-4 increases, the depth DT may increase.

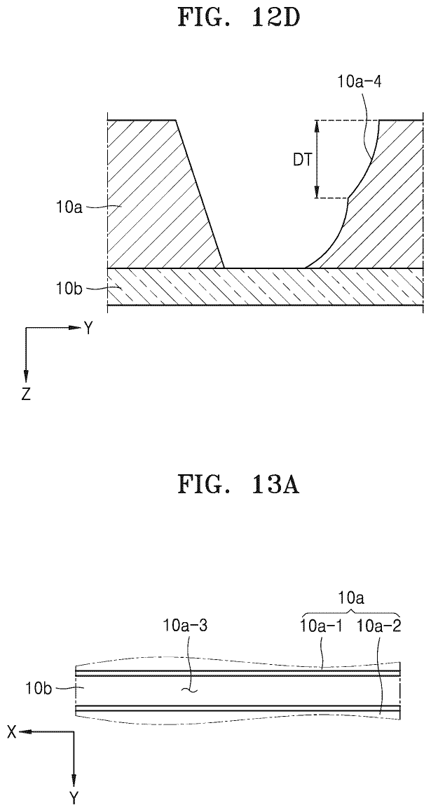

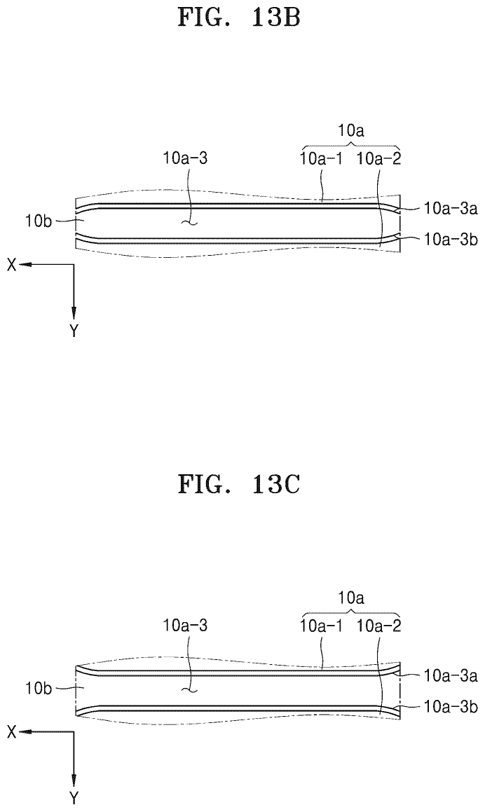

FIGS. 13A to 13C are schematic backside views of the opening area shown in FIG. 12A.

Referring to FIGS. 13A to 13C, a backside shape (e.g., a shape of the display apparatus viewed in a Z axis direction, or a shape of the display apparatus viewed from the bottom surface to the top surface with the substrate 10b disposed on the upper portion and the support substrate 10a disposed on the lower portion) of the opening area 10a-3 may be various. As an example, the backside shape of the opening area 10a-3 may be a line shape as shown in FIG. 13A. For example, the boundary area 10a-1a of the first support substrate 10a-1 and the boundary area 10a-2a of the second support substrate 10a-2 defining a portion of the opening area 10a-3 may be a straight line. For example, a portion defining another portion of the opening area 10a-3 and where a slope surface of the first support substrate 10a-1 meets/intersects the substrate 10b and a portion where a slope surface of the second support substrate 10a-2 meets/intersects the substrate 10b may be straight lines.

In another example, as shown in FIG. 13B, a backside shape of the opening area 10a-3 may have a shape such that at least one of at least a portion of a first end portion 10a-3a of a slope surface of the first support substrate 10a-1 and at least a portion of a second end portion 10a-3b of a slope surface of the second support substrate 10a-2 may protrude to the inside of the opening area 10a-3. For example, as shown in FIG. 13B, at least one of the first end portions 10a-3a of the slope surface of the first support substrate 10a-1 disposed in a lengthwise direction of the slope surface of the first support substrate 10a-1 may protrude to the opening area 10a-3. For example, at least one of the boundary area 10a-1a of the first support substrate 10a-1 and a boundary area where a slope surface of the first support substrate 10a-1 meets/intersects the substrate 10b may protrude to the opening area 10a-3. For example, as shown in FIG. 13B, at least one of second end portions 10a-3b of the slope surface of the second support substrate 10a-2 disposed in the lengthwise direction of the slope surface of the second support substrate 10a-2 may protrude to the opening area 10a-3. For example, at least one of the boundary area 10a-2a of the second support substrate 10a-2 and a boundary area where a slope surface of the second support substrate 10a-2 meets/intersects the substrate 10b may protrude to the opening area 10a-3. For example, at least one of the entire end portion of the slope surface of the first support substrate 10a-1 and the entire end portion of the slope surface of the second support substrate 10a-2 may protrude to the opening area 10a-3. For example, at least one of a portion of the end portion of the slope surface of the first support substrate 10a-1 and a portion of the end portion of the slope surface of the second support substrate 10a-2 may protrude to the opening area 10a-3.

In another example, as shown in FIG. 13C, the end portion of the opening area 10a-3 may be formed to be extended. For example, the opening area 10a-3 may be extended from at least one of the first end portions 10a-3a of the slope surface of the first support substrate 10a-1 and/or at least one of the second end portions 10a-3b of the slope surface of the second support substrate 10a-2. As an example, referring to FIG. 13C, at least one of the first end portion disposed on the upper right among the first end portions 10a-3a, the first end portion disposed on the upper left among the first end portions 10a-3a, the second end portion disposed on the lower right among the second end portions 10a-3b, and the second end portion disposed on the lower left among the second end portions 10a-3b may be formed in a direction away from the center portion of the opening area 10a-3. For example, at least one of the end portions of the opening area 10a-3 may have a shape similar to a funnel shape. For example, the first end portion 10a-3a may denote at least a portion of the end portion of the slope surface of the first support substrate 10a-1, and the second end portion 10a-3b may denote at least a portion of the end portion of the slope surface of the second support substrate 10a-2.

The opening area 10a-3 may be formed by a method similar to the manufacturing method shown in FIGS. 6A to 6E, the manufacturing method shown in FIGS. 8A to 8E, or the manufacturing method shown in FIGS. 10A to 10D.

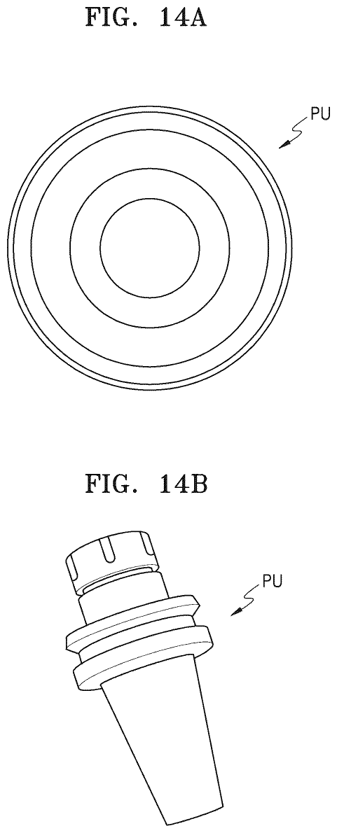

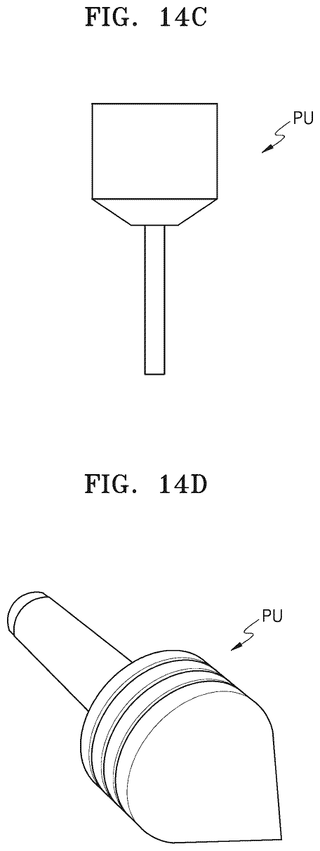

FIGS. 14A to 14D are schematic views showing embodiments of the cutting unit used in the method of manufacturing the display apparatus according to an embodiment.

Referring to FIGS. 14A to 14D, the cutting unit PU may include a cutter having various shapes. As an example, the cutting unit PU may have a disc shape as shown in FIG. 14A. For example, the lateral shape of the cutting unit PU may be similar to the shape shown in FIG. 6B.

The cutting unit PU may have a cone shape as shown in FIG. 14B. For example, as a surface where the cutting unit PU is in contact with the support substrate is inclined with respect to the lengthwise direction of the cutting unit PU, an inner surface of the reference groove MS-la processing by the cutting unit PU or a cut cross-section of the support substrate 10a cut along the cutting line CL may have an inclined shape.

As shown in FIG. 14C, a portion of the cutting unit PU, which forms the reference groove MS-la in the support substrate 10a or form the cutting line CL, may have a cylindrical shape. For example, the inner surface of the reference groove MS-la or a cut cross-section of the support substrate 10a cut along the cutting line CL may have a straight line shape.

As shown in FIG. 14D, a portion of the cutting unit PU, which forms the reference groove MS-la in the support substrate 10a or form the cutting line CL, may have a conical shape. For example, the inner surface of the reference groove MS-la processed by the cutting unit PU or a cut cross-section of the support substrate 10a cut along the cutting line CL may have an inclined shape.

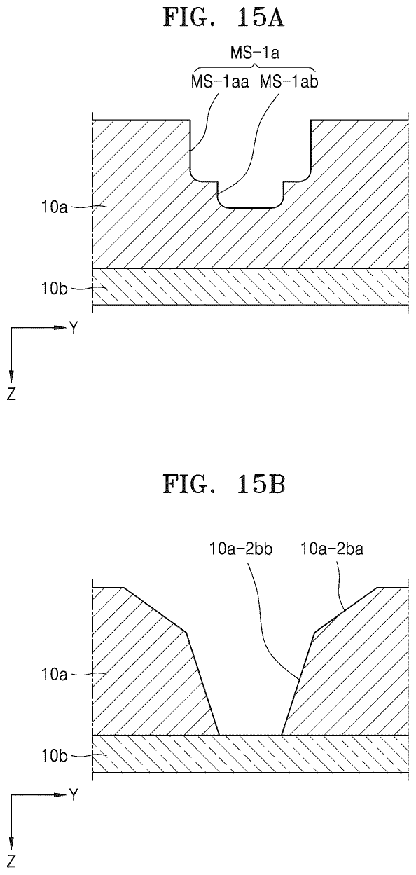

FIGS. 15A and 15B are schematic cross-sectional views of some of the manufacturing of the display apparatus according to an embodiment.

Referring to FIG. 15A, the reference groove MS-la formed by the cutting unit may be formed to have a shape stepped from a surface of the support substrate 10a. As an example, the reference groove MS-la may include at least two reference grooves. Hereinafter, for convenience of description, the case where the reference groove MS-la includes two reference grooves is described in detail.

The reference groove MS-la may include a first reference groove MS-1aa and a second reference groove MS-lab connected to each other. For example, the width (e.g., measured in a Y axis direction in FIG. 15A) of the first reference groove MS-1aa and the width (e.g., measured in a Y axis direction in FIG. 15A) of the second reference groove MS-lab may be different from each other. For example, the width of the first reference groove MS-1aa may be greater than the width of the second reference groove MS-lab. For example, the method of forming the reference groove MS-la may be the same as or similar to the method described with reference to FIG. 6B, 8B, or 10B. For example, in the case where the reference groove MS-la includes three or more reference grooves, the widths of the reference grooves may sequentially increase as the distance from the substrate 10b increases.

In case that the above operation is completed, the opening area 10a-3 may be formed by spraying etching solution to the reference groove MS-la. For example, in case that the etching solution is sprayed, the reference groove MS-la may be extended. For example, at least one of a slope surface of the first support substrate 10a-1 and a slope surface of the second support substrate 10a-2 defining the opening area 10a-3 may include slope surfaces having different slope angles. For example, as shown in FIG. 6E, the slope angle may denote an angle formed by the slope surface with respect to a surface of the substrate 10b.

In the case where the plurality of slope surfaces are formed, as shown in FIG. 15B, not only the slope surface of the second support substrate 10a-2 may include two slope surfaces but also the slope surface of the second support substrate 10a-2 may include three or more slope surfaces. For example, a slop angle of the plurality of slope surfaces may increase as being closer to the substrate 10b. As an example, in FIG. 15B, a slope angle of a first slope surface 10a-2ba may be less than a slope angle of a second slope surface 10a-2bb.

In the display apparatus according to embodiments, after the substrate is bent, a portion of the support substrate may elastically support a bent portion of the substrate. A method of manufacturing the display apparatus according to embodiments may reduce the occurrence of foreign materials although the display apparatus is manufactured.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display apparatus comprising:
a support substrate including a first support substrate and a second support substrate spaced apart from each other;
a substrate disposed on the support substrate;
a display layer disposed on a portion of the substrate disposed on the first support substrate; and
a thin-film encapsulation layer disposed to cover the display layer,
wherein a surface of the first support substrate and a surface of the second support substrate facing each other include a slope surface.

2. The display apparatus of claim 1, wherein one of the surface of the first support substrate and the surface of the second support substrate facing each other includes a groove extending in a direction away from another one of the surface of the first support substrate and the surface of the second support substrate facing each other.

3. The display apparatus of claim 2, wherein a maximum width of the groove is greater than 0 μm and is equal to or less than 50 μm.

4. The display apparatus of claim 1, wherein
each of the first support substrate and the second support substrate includes a plurality of sides, and
at least one of the plurality of sides of the first support substrate or at least one of the plurality of sides of the second support substrate includes the slope surface.

5. The display apparatus of claim 1, further comprising:
a protective layer disposed on the support substrate and the substrate.

6. The display apparatus of claim 5, wherein the protective layer overlaps a region in which the first support substrate is spaced apart from the second support substrate in a plan view.

7. The display apparatus of claim 5, wherein the protective layer includes amorphous silicon.

8. The display apparatus of claim 1, wherein the substrate is bent to form a bent portion.

9. The display apparatus of claim 8, further comprising:
a bending protective layer disposed on the bent portion of the substrate.

10. A method of manufacturing a display apparatus, the method comprising:
disposing a second base substrate on a first base substrate;
forming a display layer and a thin-film encapsulation layer on the second base substrate;
forming a reference groove in the first base substrate;
disposing an etching protective layer on the thin-film encapsulation layer; and
forming an opening area by spraying an etching solution to the first base substrate and by expanding the reference groove.

11. The method of claim 10, further comprising:
forming the reference groove by removing a portion of the first base substrate by a cutter or a laser beam.

12. The method of claim 10, further comprising:
forming a protective layer on the first base substrate.

13. The method of claim 12, wherein the protective layer overlaps the reference groove in a plan view.

14. The method of claim 12, wherein the protective layer includes amorphous silicon.

15. The method of claim 10, wherein a depth of the reference groove has a linear relationship with a taper angle of a surface of the first base substrate disposed around the opening area.

16. The method of claim 10, further comprising:
forming a groove in a boundary area of a surface of the first base substrate defining the opening area.

17. The method of claim 16, wherein a maximum width of the groove is greater than 0 μm and is equal to or less than 50 μm.

18. The method of claim 10, further comprising:
separating the first base substrate and the second base substrate along an edge portion of the display layer.

19. The method of claim 10, further comprising:
disposing a bending protective layer on the second base substrate to overlap the opening area in a plan view.

20. The method of claim 19, further comprising:
bending the second base substrate around an arbitrary bending axis overlapping the bending protective layer.

21. The method of claim 10, further comprising:
cutting the first base substrate and the second base substrate along a cutting line spaced apart from an edge portion of the display layer and the thin-film encapsulation layer.

22. A method of manufacturing a display apparatus, the method comprising:
disposing a second base substrate on a first base substrate;
forming a display layer and a thin-film encapsulation layer on the second base substrate;
forming a cutting groove in the second base substrate;
disposing an etching protective layer on the thin-film encapsulation layer; and
separating a portion of the first base substrate from another portion of the first base substrate along the cutting groove by spraying an etching solution to a surface of the first base substrate different from a surface of the first base substrate on which the display layer is disposed.
